(19) United States
(12) Patent Application Publication
(10) Pub. No.: US 2026/0343975 A1
(43) Pub. Date: Oct. 29, 2026

(54) SEMICONDUCTOR DEVICE AND METHOD OF MANUFACTURE

(71) Applicant: Taiwan Semiconductor Manufacturing Co., Ltd., Hsinchu (TW)

(72) Inventors: Ching Chang, Hsinchu (TW); Chien-Wei Lee, Kaohsiung City (TW); Chien-I Kuo, Zhubei City (TW); Ming-Hua Yu, Hsinchu (TW)

(21) Appl. No.: 19/738,112

(22) Filed: Jul. 10, 2026

Related U.S. Application Data
(63) Continuation of application No. 18/962,312, filed on Nov. 27, 2024.

(51) Int. Cl. H10D 62/53; H10D 30/00; H10D 30/01; H10D 62/10; H10D 62/40; H10P 14/20

(52) U.S. Cl. CPC H10D 62/53; H10D 30/019; H10D 62/405; H10P 14/3466; H10D 30/501; H10D 62/121

(57) ABSTRACT

A method includes depositing a multi-layer stack on a semiconductor substrate, wherein a top surface of the semiconductor substrate is parallel to the (110) crystallographic plane, etching the multi-layer stack and the semiconductor substrate to form a fin, forming a first recess in the fin adjacent the dummy gate, wherein a bottom surface of the first recess in the fin is coplanar with the (110) crystallographic plane, and forming an epitaxial source/drain region in the first recess, wherein the epitaxial source/drain region includes a bottom portion of the epitaxial source/drain region, and a top portion of the epitaxial source/drain region over the bottom portion of the epitaxial source/drain region, wherein when observed along the <11̅0> crystallographic direction, a number of dislocations in the top portion of the epitaxial source/drain region is greater than a number of dislocations in the bottom portion of the epitaxial source/drain region.

### CROSS-REFERENCE TO RELATED APPLICATIONS

This application is a continuation of U.S. patent application Ser. No. 18/962,312 filed on Nov. 27, 2024, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5, 6A, 6B, 6C, 7A, 7B, 7C, 8A, 8B, 8C, 9, 10, 11A, 11B, 11C, 12A, 12B, 12C, 12D, 12E, 12F, 13A, 13B, 13C, 14A, 14B, 14C, 15A, 15B, 15C, 16A, 16B, 16C, 17A, 17B, 17C, 18A, 18B, 18C, 19A, 19B, 19C, 20A, 20B, and 20C are cross-sectional views of intermediate stages in the manufacturing of nano-FETs, in accordance with some embodiments.

### DETAILED DESCRIPTION OF THE DRAWINGS

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide semiconductor devices having improved performance and methods of forming the same. The semiconductor devices may be nanostructure field-effect transistors (nano-FETs, also referred to as nanosheet field-effect transistors (NSFETs), nanowire field-effect transistors (NWFETs), or gate-all-around field-effect transistors (GAAFETs)). These embodiments include methods applied to forming semiconductor nanostructures over a semiconductor fin and a semiconductor substrate. The semiconductor fin may be formed to protrude from the semiconductor substrate, wherein top surfaces of the semiconductor fin and the semiconductor substrate are oriented along the (110) crystallographic plane. A recess is formed in the semiconductor nanostructures and the semiconductor fin. In an embodiment, bottom surfaces of the recess in the semiconductor fin may be substantially coplanar with the (110) crystallographic plane of the semiconductor substrate. A source/drain region is then formed in the recess. For example, the source/drain region may be formed by performing a first process to epitaxially grow a first portion of the source/drain region in the recess, and subsequently performing a second process to epitaxially grow a second portion of the source/drain region over the first portion of the source/drain region. After the formation of the source/drain region, an angle between each dislocation in the source/drain region and the horizontal <001> crystallographic direction may be in a range from 30° to 40°, wherein the dislocation in the source/drain region is observed along the <11̅0> crystallographic direction (also referred to subsequently as the specific zone axis). In addition a number of dislocations in the first portion of the source/drain region is smaller than a number of dislocations in the second portion of the source/drain region. Further, when observed along the <110> crystallographic direction, the second portion of the source/drain region may comprise a top portion having a triangular cross-section with sloping sidewalls that intersect at a topmost point of the top portion of the second portion of the source/drain region. The sloping sidewalls may comprise angled facets that are oriented along the (111) crystallographic plane. A bottom portion of the second portion of the source/drain region may be disposed below the top portion of the second portion of the source/drain region. The bottom portion of the second portion of the source/drain region may have sidewalls that comprise facets that are oriented along the (001) crystallographic plane.

Advantageous features of one or more embodiments disclosed herein may include the forming of the source/drain region in the recess in the semiconductor nanostructures and the semiconductor fin using the first process and the second process, wherein the bottom surfaces of the recess in the semiconductor fin may be substantially coplanar with the (110) crystallographic plane of the semiconductor substrate allowing for improved control of dislocation patterns in the source/drain region (e.g., an angle between each dislocation in the source/drain region and the horizontal <001> direction may be in a range from 30° to 40°), and improved strain distribution in channel regions of the semiconductor nanostructures. This results in an increase in carrier mobility, and hence device performance is enhanced. In addition, the use of the first process and the second process to form the source/drain region in the recess in the semiconductor nanostructures and the semiconductor fin, wherein the bottom surfaces of the recess in the semiconductor fin may be substantially coplanar with the (110) crystallographic plane of the semiconductor substrate, allows for the source/drain region to be formed with a smaller number of dislocations in the source/drain region. This may lead to reduced carrier scattering, which directly improves electron mobility and overall current flow. As a result, device performance and reliability is improved.

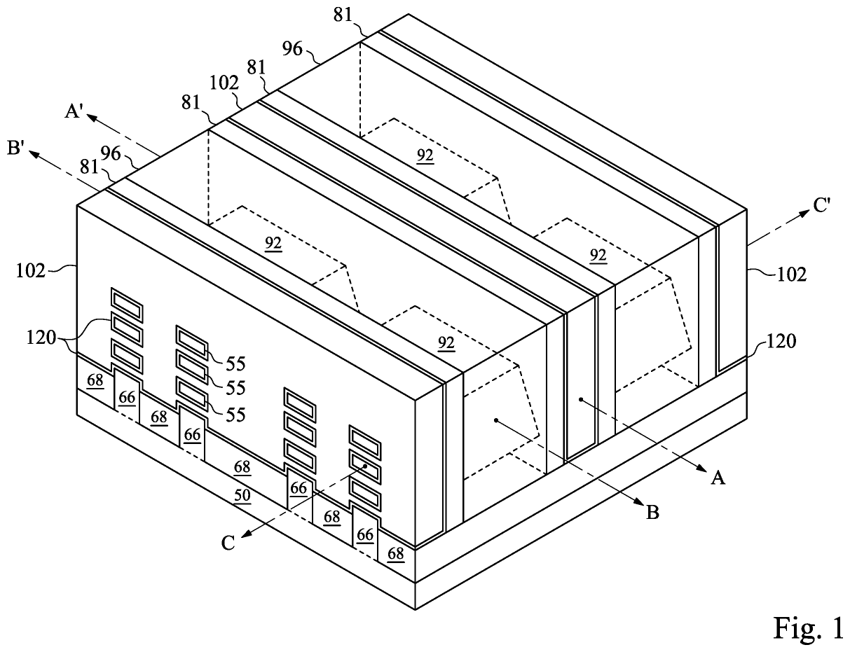

FIG. 1 illustrates an example of nano-FETs (e.g., nanowire FETs, nanosheet FETs, or the like) in a three-dimensional view, in accordance with some embodiments. The nano-FETs comprise nanostructures 55 (e.g., nanosheets, nanowire, or the like) over fins (or a protrusion/base portion) 66 on a substrate 50 (e.g., a semiconductor substrate), wherein the nanostructures 55 act as channel regions for the nano-FETs. The nanostructures 55 may include p-type nanostructures, n-type nanostructures, or a combination thereof. Shallow trench isolation (STI) regions 68 are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the STI regions. Additionally, although bottom portions of the fins 66 are illustrated as being single, continuous materials with the substrate 50, the bottom portions of the fins 66 and/or the substrate 50 may comprise a single material or a plurality of materials. In this context, the fins 66 refer to the portion extending between the neighboring STI regions 68.

Gate dielectric layers 120 are over top surfaces of the fins 66 and along top surfaces, sidewalls, and bottom surfaces of the nanostructures 55. Gate electrodes 102 are over the gate dielectric layers 120. Epitaxial source/drain regions 92 are disposed on the fins 66 on opposing sides of the gate dielectric layers 120 and the gate electrodes 102. First spacers 81 may be disposed on sidewalls of the gate dielectric layers.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is parallel to cross-section A-A′ and extends through epitaxial source/drain regions 92 of multiple nano-FETs. Cross-section C-C′ is perpendicular to cross-section A-A′ and is parallel to a longitudinal axis of a fin 66 of the nano-FET and in a direction of, for example, a current flow between the epitaxial source/drain regions 92 of the nano-FET. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFets).

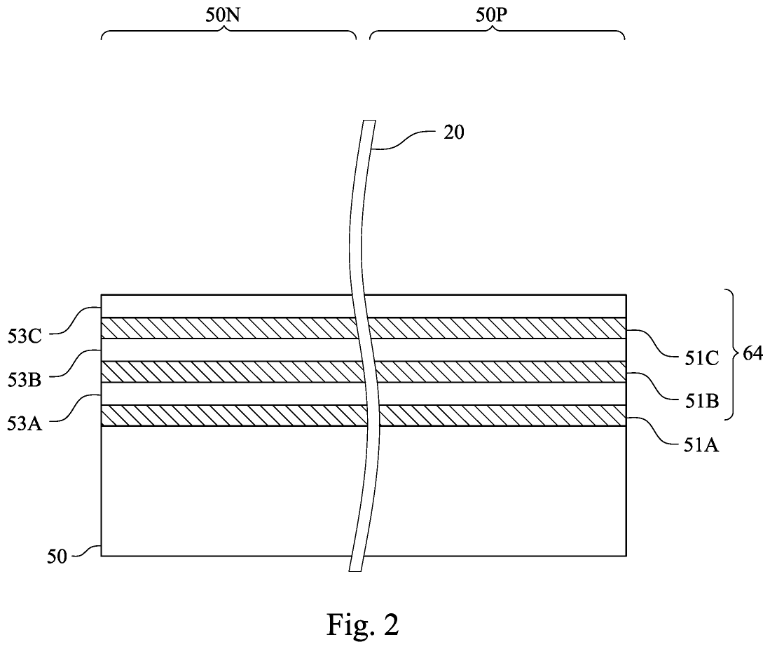

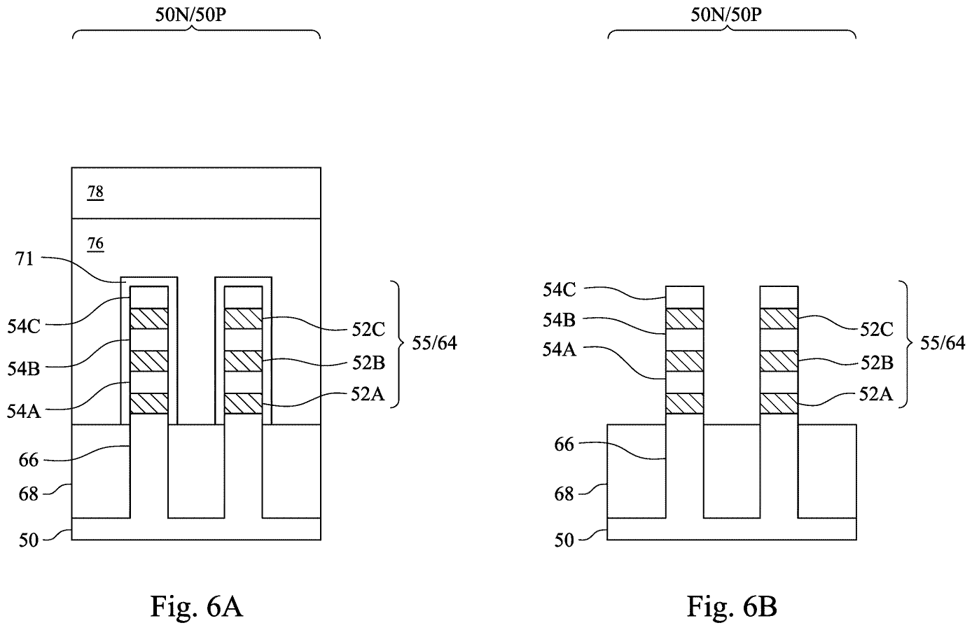

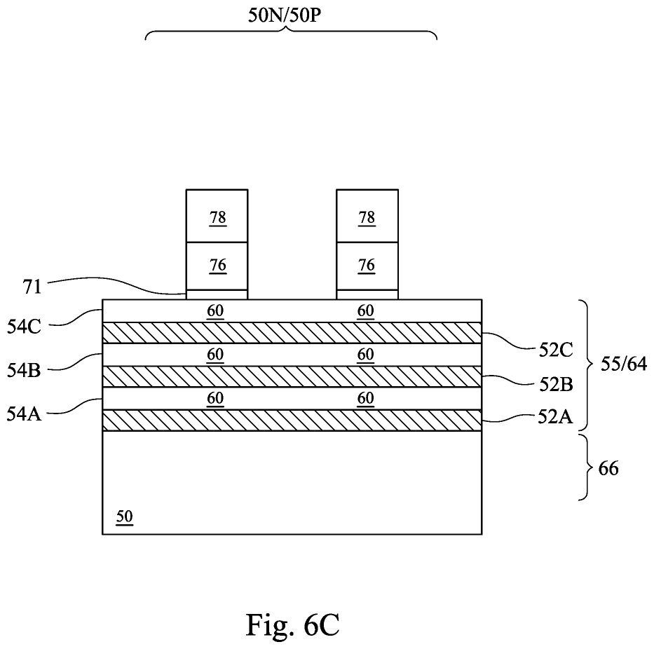

FIGS. 2 through 20C are cross-sectional views of intermediate stages in the manufacturing of nano-FETs, in accordance with some embodiments. FIGS. 2 through 5, 6A, 7A, 8A, 11A, 12A, 13A, 14A, 15A, 16A, 17A, 18A, 19A, and 20A illustrate reference cross-section A-A′ illustrated in FIG. 1. FIGS. 6B, 7B, 8B, 11B, 12B, 12D, 12E, 12F, 13B, 14B, 15B, 16B, 17B, 18B, 19B, and 20B illustrate reference cross-section B-B′ illustrated in FIG. 1, wherein the cross-section B-B′ is observed along the <11̅0> crystallographic direction. FIGS. 6C, 7C, 8C, 9, 10, 11C, 12C, 13C, 14C, 15C, 16C, 17C, 18C, 19C, and 20C illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. In an embodiment, the substrate 50 may be a (110) substrate that comprises a semiconductor material, such as silicon, or the like, that has been cut or grown such that a top surface of the substrate 50 is parallel to the (110) crystallographic plane. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-51C (collectively referred to as first semiconductor layers 51) and second semiconductor layers 53A-53C (collectively referred to as second semiconductor layers 53). For purposes of illustration and as discussed in greater detail below, the first semiconductor layers (which may also referred to as sacrificial layers) 51A, 51B and 51C will be removed and the second semiconductor layers (which may also referred to as channel layers) 53A, 53B and 53C will be patterned to form channel regions of nano-FETs in the n-type region 50N and the p-type region 50P. However, in some embodiments the first semiconductor layers 51A, 51B and 51C may be removed and the second semiconductor layers 53A, 53B and 53C may be patterned to form channel regions of nano-FETs in the n-type region 50N, and the second semiconductor layers 53A, 53B and 53C may be removed and the first semiconductor layers 51A, 51B and 51C may be patterned to form channel regions of nano-FETs in the p-type region 50P. In some embodiments the second semiconductor layers 53A, 53B and 53C may be removed and the first semiconductor layers 51A, 51B and 51C may be patterned to form channel regions of nano-FETs in the n-type region 50N, and the first semiconductor layers 51A, 51B and 51C may be removed and the second semiconductor layers 53A, 53B and 53C may be patterned to form channel regions of nano-FETs in the p-type region 50P. In some embodiments, the second semiconductor layers 53A, 53B and 53C may be removed and the first semiconductor layers 51A, 51B and 51C may be patterned to form channel regions of nano-FETs in both the n-type region 50N and the p-type region 50P.

The multi-layer stack 64 is illustrated as including three layers of the first semiconductor layers 51 and three layers of the second semiconductor layers 53 for illustrative purposes. In some embodiments, the multi-layer stack 64 may include two or more of the first semiconductor layers 51 and two or more of the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material suitable for p-type nano-FETs, such as silicon germanium, or the like, and the second semiconductor layers 53 may be formed of a second semiconductor material suitable for n-type nano-FETs, such as silicon, silicon carbon, or the like. The multi-layer stack 64 is illustrated as having a bottommost semiconductor layer suitable for p-type nano-FETs for illustrative purposes. In some embodiments, multi-layer stack 64 may be formed such that the bottommost layer is a semiconductor layer suitable for n-type nano-FETs.

The first semiconductor materials and the second semiconductor materials may be materials having a high etch selectivity to one another. As such, the first semiconductor layers 51 of the first semiconductor material may be removed without significantly removing the second semiconductor layers 53 of the second semiconductor material thereby allowing the second semiconductor layers 53A, 53B and 53C to be patterned to form channel regions of nano-FETs. Similarly, in embodiments in which the second semiconductor layers 53 are removed and the first semiconductor layers 51A, 51B and 51C are patterned to form channel regions, the second semiconductor layers 53 of the second semiconductor material may be removed without significantly removing the first semiconductor layers 51 of the first semiconductor material, thereby allowing the first semiconductor layers 51A, 51B and 51C to be patterned to form channel regions of nano-FETs.

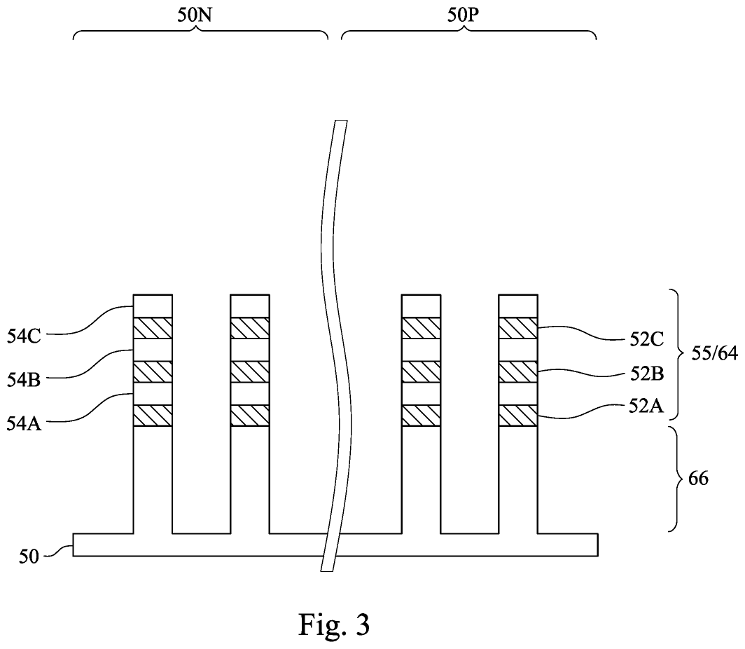

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-52C (collectively referred to as the first nanostructures 52) from the first semiconductor layers 51 and define second nanostructures 54A-54C (collectively referred to as the second nanostructures 54) from the second semiconductor layers 53. The first nanostructures 52 and the second nanostructures 54 may be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

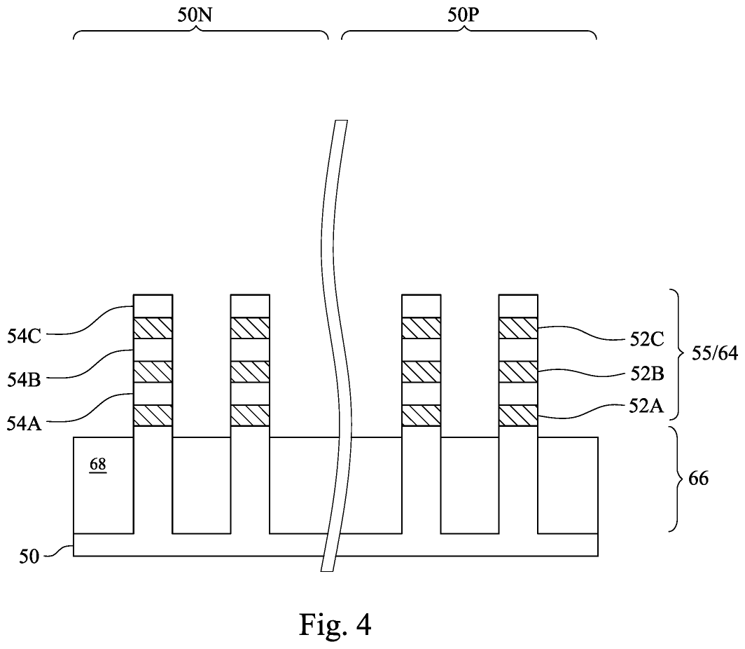

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 in the n-type region 50N and the p-type region 50P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

The process described above with respect to FIGS. 2 through 4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting first nanostructures 52) and the second semiconductor layers 53 (and resulting second nanostructures 54) are illustrated and discussed herein as comprising the same materials in the p-type region 50P and the n-type region 50N for illustrative purposes only. As such, in some embodiments one or both of the first semiconductor layers 51 and the second semiconductor layers 53 may be different materials or formed in a different order in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities (also referred to as dopants) may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities (also referred to as dopants) may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

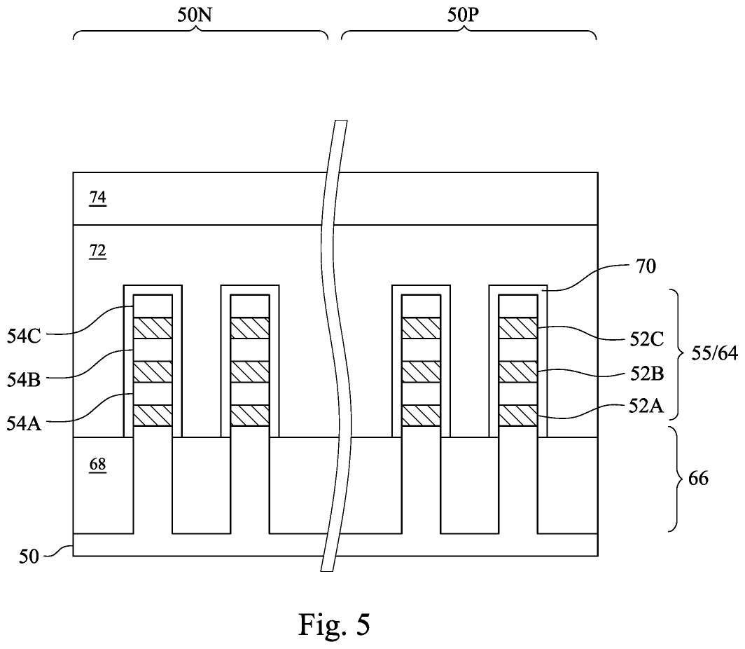

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A through 20C illustrate various additional steps in the manufacturing of embodiment devices. FIGS. 6A through 20C illustrate features in either the n-type region 50N or the p-type region 50P. In FIGS. 6A through 6C, the mask layer 74 (see FIG. 5) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions 60 of the fins 66 and/or the nanostructures 55. The pattern of the masks 78 may be used to physically separate each of the dummy gates 76 from adjacent dummy gates 76. The dummy gates 76 may also have a lengthwise direction substantially perpendicular to the lengthwise direction of respective fins 66.

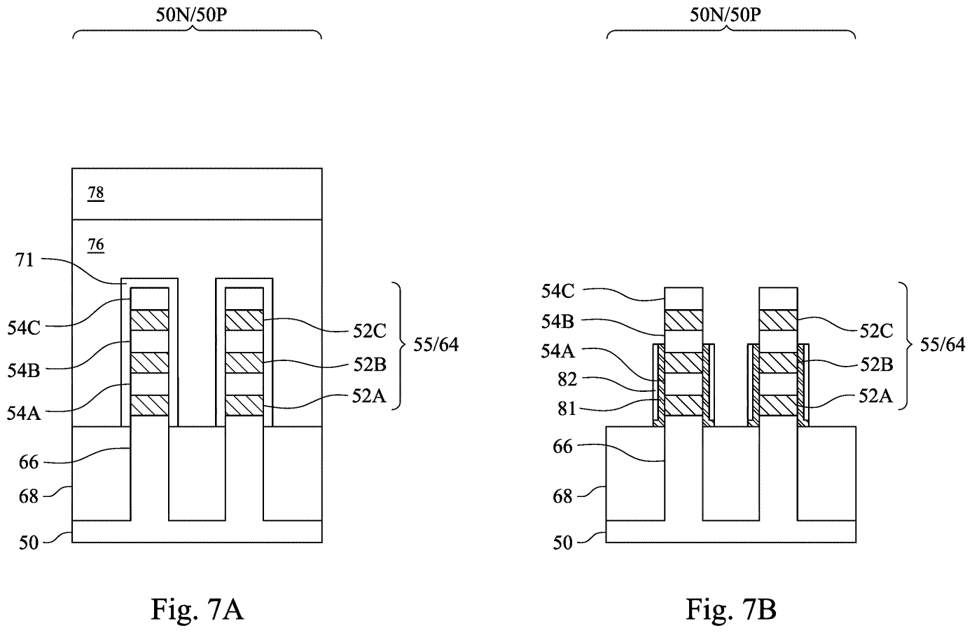

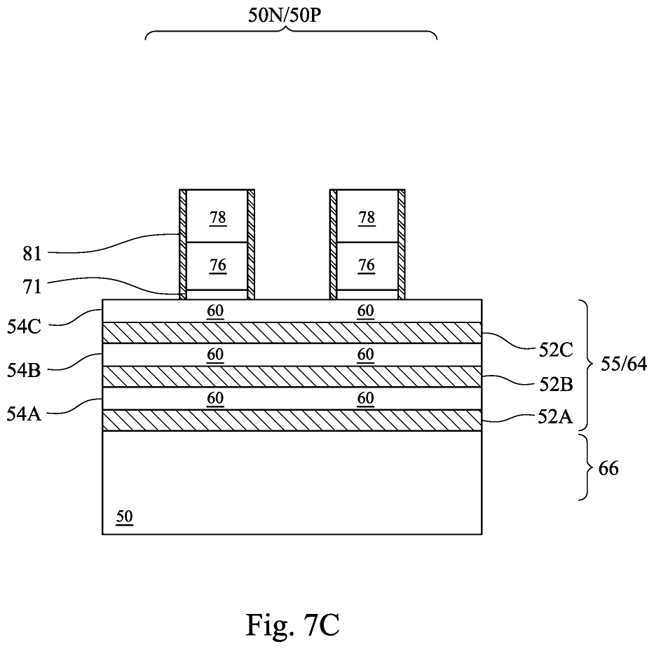

In FIGS. 7A through 7C, first spacers 81 and second spacers 82 are formed on sidewalls of the fins 66 and/or nanostructures 55. The first spacers 81 and the second spacers 82 may be formed by sequentially forming a first spacer layer and a second spacer layer over the structures illustrated in FIGS. 6A through 6C. The first spacer layer and the second spacer layer will be subsequently patterned to form the first spacers 81 and the second spacers 82, respectively, which are subsequently used for forming self-aligned source/drain regions. The first spacer layer may be formed on top surfaces of the STI regions 68; top surfaces and sidewalls of the fins 66, the nanostructures 55, and the masks 78; and sidewalls of the dummy gates 76 and the dummy gate dielectric 71. The second spacer layer is deposited over the first spacer layer. The first spacer layer may be formed of silicon oxide, silicon nitride, silicon oxynitride, or the like, using techniques such as thermal oxidation or deposited by CVD, ALD, or the like. The second spacer layer may be formed of a material having a different etch rate than the material of the first spacer layer, such as silicon oxide, silicon nitride, silicon oxynitride, or the like, and may be deposited by CVD, ALD, or the like.

After the first spacer layer is formed and prior to forming the second spacer layer, implants for lightly doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 1×10¹⁵ atoms/cm³ to about 1×10¹⁹ atoms/cm³. An anneal may be used to repair implant damage and to activate the implanted impurities.

Referring further to FIGS. 7A through 7C, the first spacer layer and the second spacer layer are etched to form the first spacers 81 and the second spacers 82, respectively. As will be discussed in greater detail below, the first spacers 81 and the second spacers 82 act to self-aligned subsequently formed source drain regions, as well as to protect sidewalls of the fins 66 and/or nanostructures 55 during subsequent processing. The first spacer layer and the second spacer layer may be etched using a suitable etching process, such as an isotropic etching process (e.g., a wet etching process), an anisotropic etching process (e.g., a dry etching process), or the like. In some embodiments, the material of the second spacer layer has a different etch rate than the material of the first spacer layer, such that the first spacer layer may act as an etch stop layer when patterning the second spacer layer and such that the second spacer layer may act as a mask when patterning the first spacer layer. For example, the second spacer layer may be etched using an anisotropic etch process wherein the first spacer layer acts as an etch stop layer, wherein remaining portions of the second spacer layer form second spacers 82 as illustrated in FIG. 7B. Thereafter, the second spacers 82 acts as a mask while etching exposed portions of the first spacer layer, thereby forming the first spacers 81 as illustrated in FIGS. 7B and 7C.

As illustrated in FIG. 7B, the first spacers 81 and the second spacers 82 are disposed on sidewalls of the fins 66 and/or nanostructures 55. As illustrated in FIG. 7C, in some embodiments, the second spacer layer may be removed from over the first spacer layer adjacent the masks 78, the dummy gates 76, and the dummy gate dielectrics 71, and the first spacers 81 are disposed on sidewalls of the masks 78, the dummy gates 76, and the dummy gate dielectrics 71. In other embodiments, a portion of the second spacer layer may remain over the first spacer layer adjacent the masks 78, the dummy gates 76, and the dummy gate dielectrics 71.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer), additional spacers may be formed and removed, and/or the like. Furthermore, the n-type and p-type devices may be formed using different structures and steps.

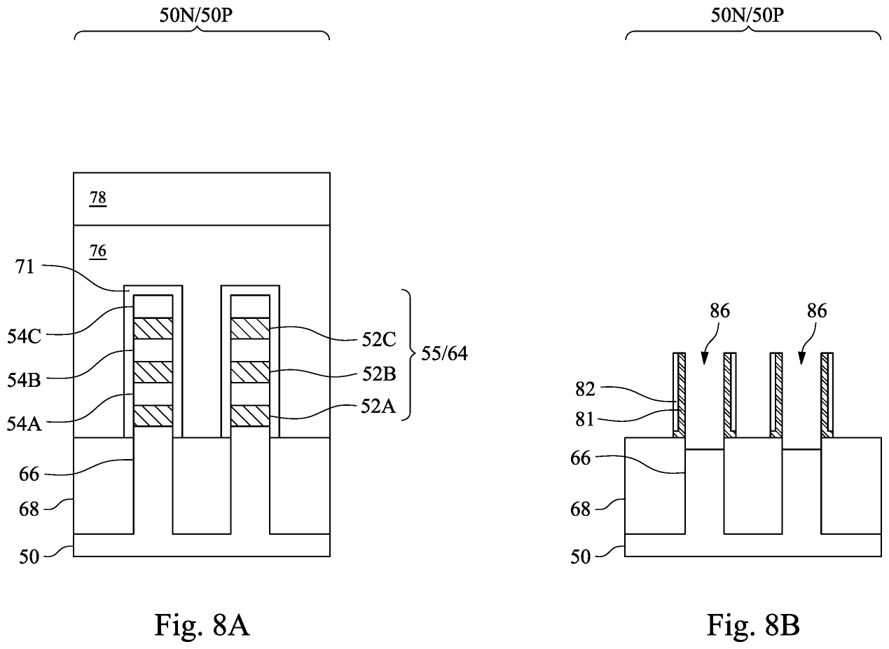

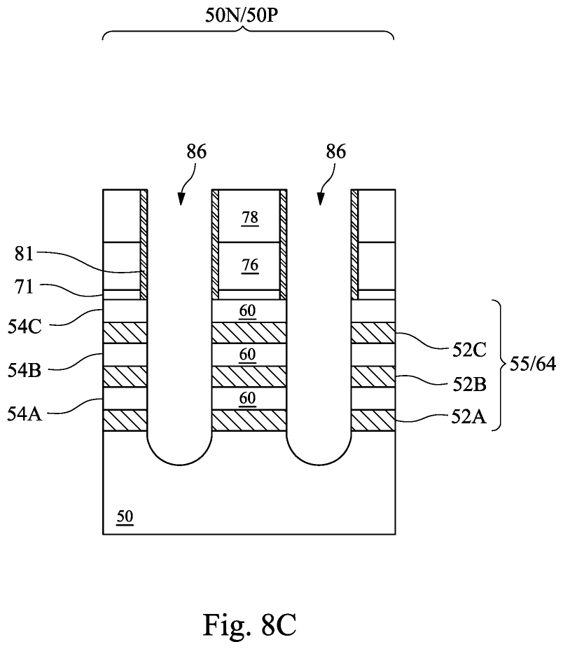

In FIGS. 8A through 8C, first recesses 86 are formed in the nanostructures 55 and the fins 66, in accordance with some embodiments. Epitaxial materials and epitaxial source/drain regions will be subsequently formed in the first recesses 86. The first recesses 86 may extend through the first nanostructures 52, the second nanostructures 54, and partially through the fins 66. In an embodiment, the nanostructures 55 and the fins 66 may be etched such that bottom surfaces of the first recesses 86 are disposed below the top surfaces of the STI regions 68 as illustrated by FIG. 8B. In other embodiments, top surfaces of the STI regions 68 may be level with bottom surfaces of the first recesses 86. In an embodiment, after forming the first recesses 86, bottom surfaces of the first recesses 86 in the fins 66 may be substantially coplanar with the (110) crystallographic plane of the substrate 50.

The first recesses 86 may be formed by etching the nanostructures 55 and the fins 66 using anisotropic etching processes, such as RIE, NBE, or the like. The first spacers 81, the second spacers 82, and the masks 78 mask portions of the fins 66, the nanostructures 55, and the substrate 50 during the etching processes used to form the first recesses 86. A single etch process or multiple etch processes may be used to etch each layer of the nanostructures 55. Timed etch processes may be used to stop the etching after the first recesses 86 reach desired depths.

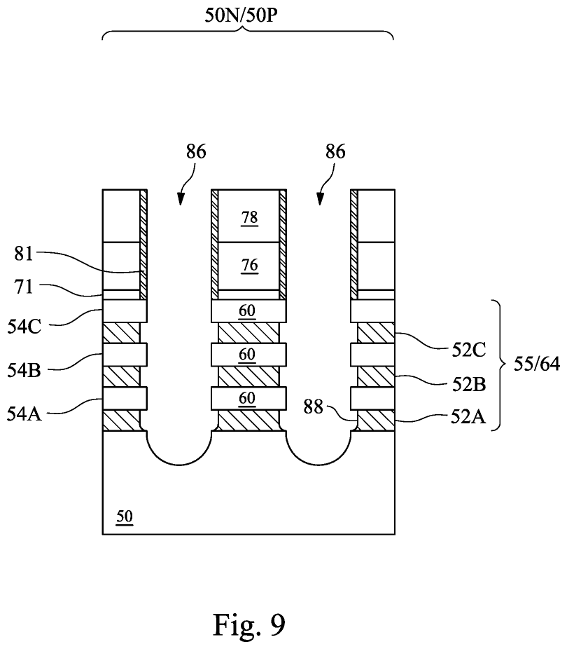

In FIG. 9, portions of sidewalls of the layers of the multi-layer stack 64 formed of the first semiconductor materials (e.g., the first nanostructures 52) exposed by the first recesses 86 are etched to form sidewall recesses 88. Although sidewalls of the first nanostructures 52 adjacent the sidewall recesses 88 are illustrated as being straight in FIG. 9, the sidewalls may be concave or convex. The sidewalls may be etched using isotropic etching processes, such as wet etching or the like. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to etch sidewalls of the first nanostructures 52.

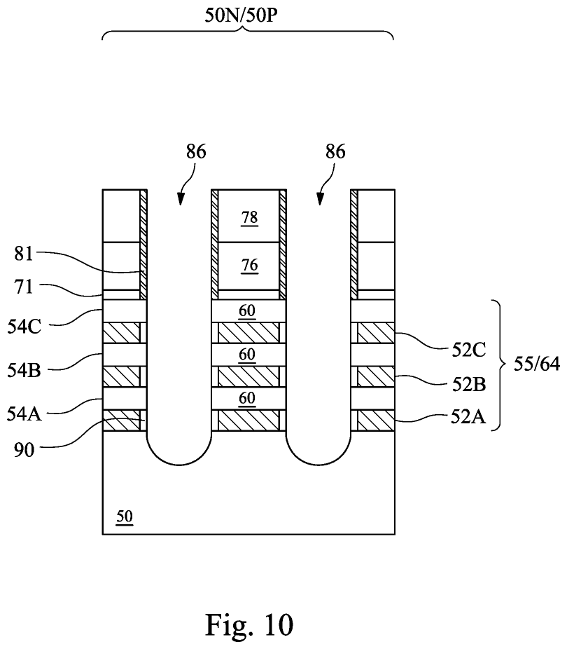

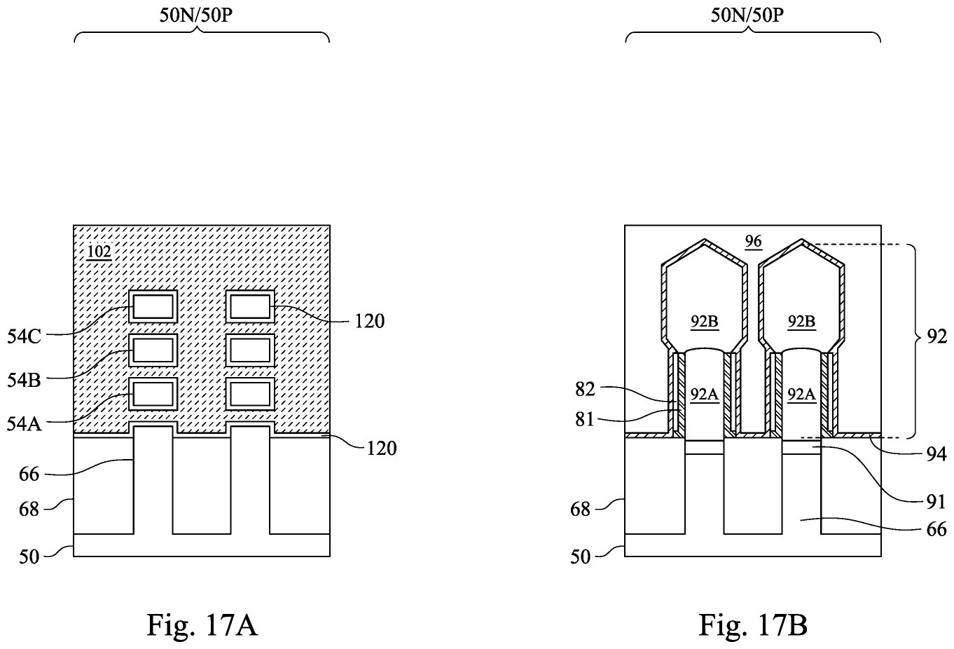

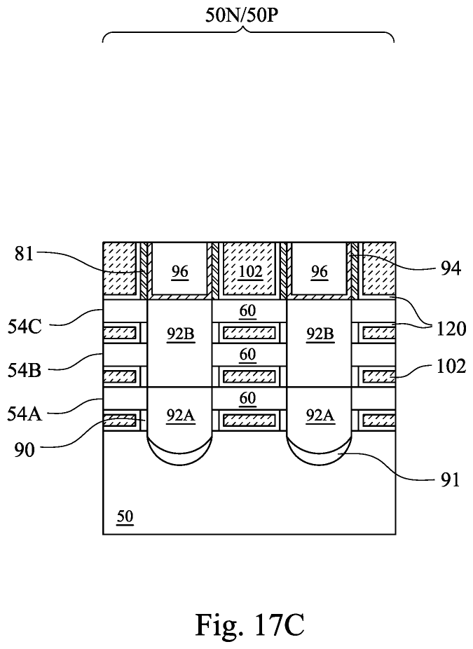

In FIG. 10, inner spacers 90 are formed in the sidewall recess 88. The inner spacers 90 may be formed by depositing an inner spacer layer (not separately illustrated) over the structures illustrated in FIG. 9. The inner spacers 90 act as isolation features between subsequently formed source/drain regions and the gate dielectric layers 120 and the gate electrodes 102 (shown subsequently in FIGS. 17A through 17C). As will be discussed in greater detail below, epitaxial source/drain regions and epitaxial materials will be formed in the first recesses 86, while the first nanostructures 52A, 52B and 52C will be replaced with the gate dielectric layers 120 and the gate electrodes 102.

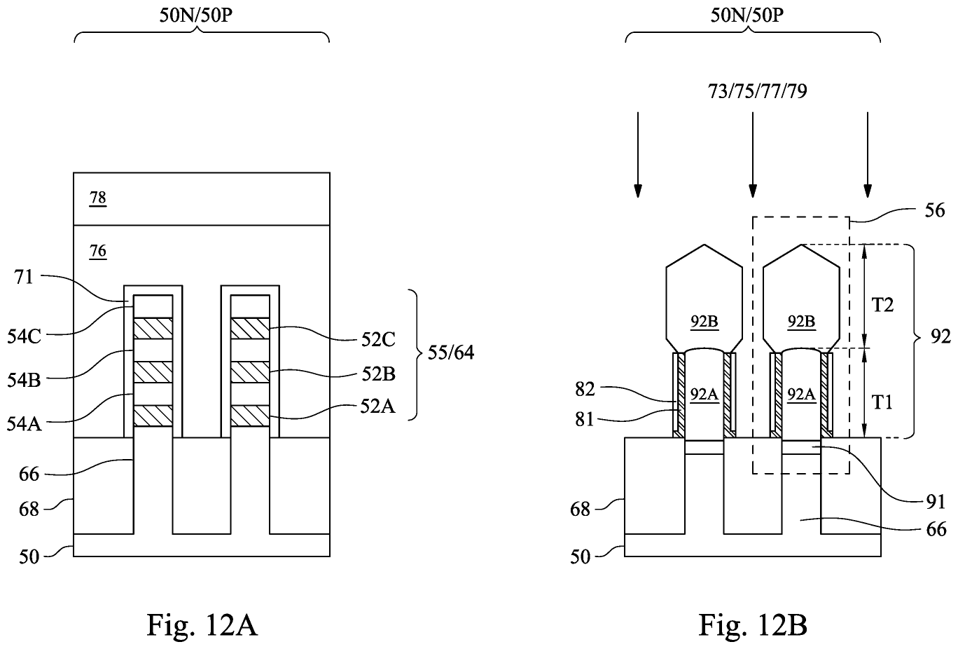

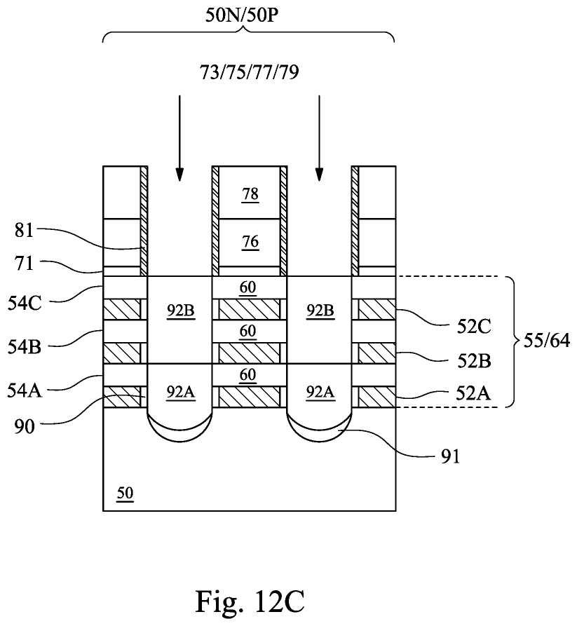

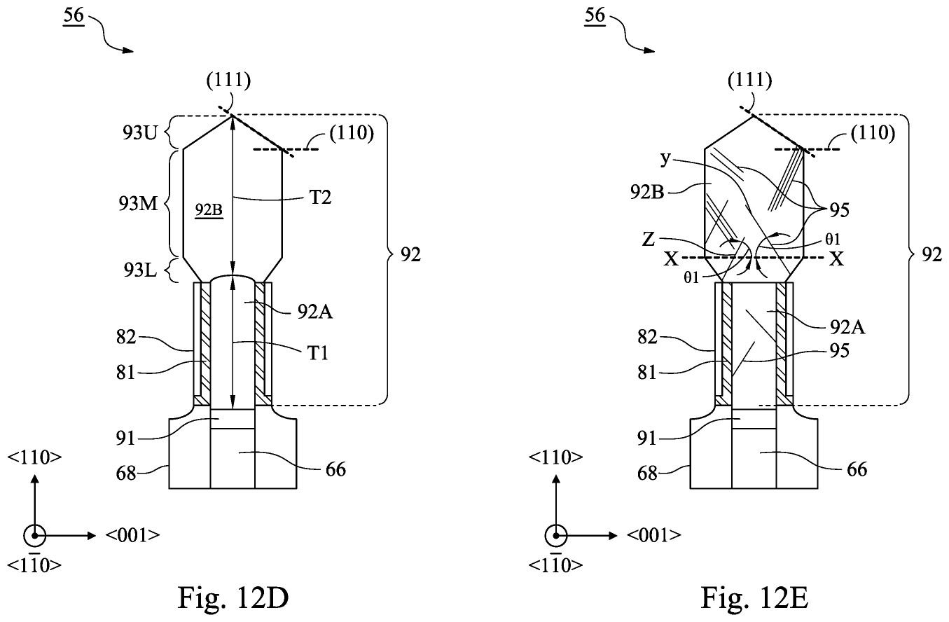

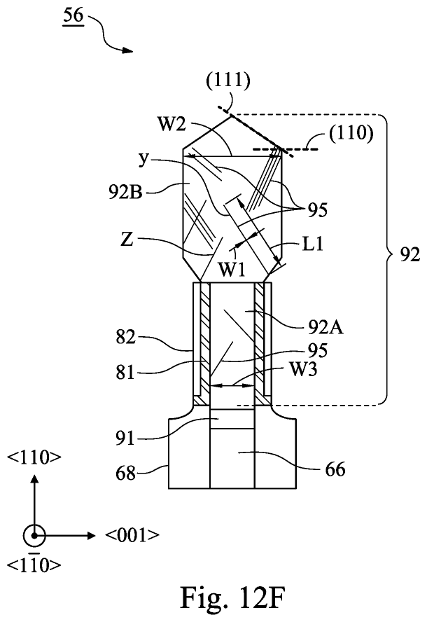

The inner spacer layer may be deposited by a conformal deposition process, such as CVD, ALD, or the like. The inner spacer layer may comprise a material such as silicon carbonitride (SiCN) or silicon oxycarbonitride (SiOCN). In other embodiments, silicon nitride or silicon oxynitride, or any suitable material, such as low-dielectric constant (low-k) materials having a k-value less than about 3.5, may be utilized. The inner spacer layer may then be anisotropically etched to form the inner spacers 90. Although outer sidewalls of the inner spacers 90 are illustrated as being flush with sidewalls of the second nanostructures 54, the outer sidewalls of the inner spacers 90 may extend beyond or be recessed from sidewalls of the second nanostructures 54. Moreover, although the outer sidewalls of the inner spacers 90 are illustrated as being straight in FIG. 10, the outer sidewalls of the inner spacers 90 may be concave or convex. The inner spacer layer may be etched by an anisotropic etching process, such as RIE, NBE, or the like. The inner spacers 90 may be used to prevent damage to subsequently formed source/drain regions (shown in FIGS. 12A through 12C) by subsequent etching processes, such as etching processes used to form the gate dielectric layers 120 and the gate electrodes 102 (shown in FIGS. 17A through 17C).

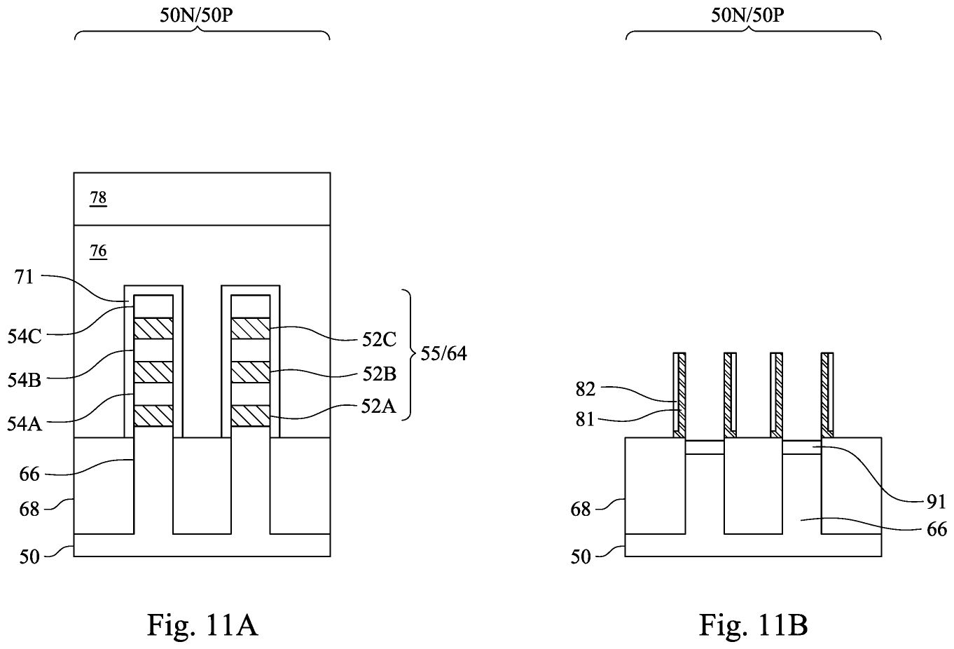

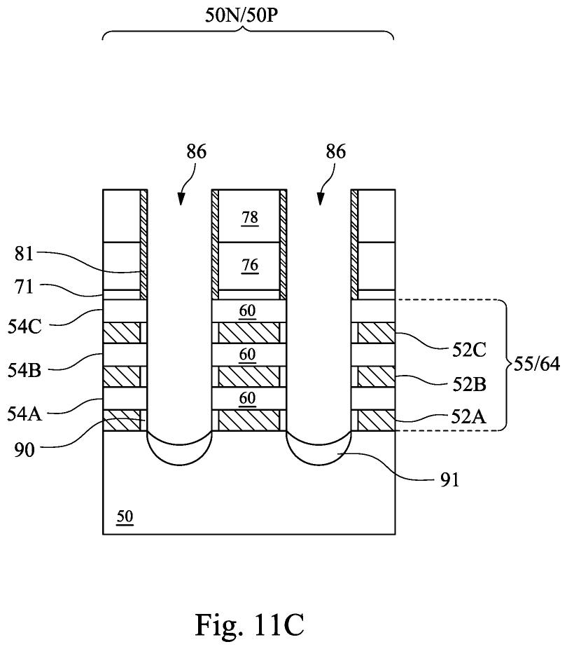

In FIGS. 11A through 11C, a first layer 91 is optionally formed to partially fill in the first recesses 86, wherein the bottom surfaces of the first recesses 86 in the fins 66 may be substantially coplanar with the (110) crystallographic plane of the substrate 50. The first layer 91 may comprise silicon, a silicon based material, or the like, which may be epitaxially grown or deposited using a process such as chemical vapor deposition (CVD), atomic layer deposition (ALD), vapor phase epitaxy (VPE), molecular beam epitaxy (MBE), or the like. Tuning of the parameters of the epitaxial growth process that is used to form the first layer 91 allows for bottom-up growth of the first layer 91 in the first recesses 86, such that growth of the first layer 91 takes place at bottom portions of the first recesses 86 before other portions of the first recesses 86. The formation of the first layer 91 is an optional step and may be omitted, and the steps described subsequently in FIGS. 12A through 12C may be performed without performing the steps described in FIGS. 11A through 11C.

In FIGS. 12A through 12C, epitaxial source/drain regions 92 are formed in the first recesses 86 over the first layer 91 (if present). In other embodiments in which the steps described above in FIGS. 11A through 11C are omitted and the first layer 91 is not present, the epitaxial source/drain regions 92 are formed in the first recesses 86 to be in physical contact with bottom surfaces (e.g., the bottom surfaces of the first recesses 86 in the fins 66 that may be substantially coplanar with the (110) crystallographic plane of the substrate 50) of the first recesses 86. FIG. 12B shows a cross-sectional view of the n-type region 50N or the p-type region 50P as observed along the <11̅0> crystallographic direction (also referred to subsequently as the specific zone axis).

Advantages can be achieved by observing the epitaxial source/drain regions 92 in the n-type region 50N or the p-type region 50P of the substrate 50 along the <11̅0> crystallographic direction (also referred to subsequently as the specific zone axis). This specific zone axis provides optimal contrast for imaging the dislocations (described subsequently) that may be disposed in the epitaxial source/drain regions 92, wherein the epitaxial source/drain regions 92 are grown over the bottom surfaces of the first recesses 86 in the fins 66 that may be substantially coplanar with the (110) crystallographic plane of the substrate 50. As a result, visibility of the dislocations may be enhanced, allowing for improved characterization of the dislocation network in the epitaxial source/drain regions 92. As an example, observing the epitaxial source/drain regions 92 in the n-type region 50N or the p-type region 50P of the substrate 50 along a different crystallographic direction to the <11̅0> crystallographic direction would result in a reduced visibility of the dislocations that are disposed in the epitaxial source/drain regions 92, and therefore a reduced ability to adequately characterize the dislocation network in the epitaxial source/drain regions 92.

In some embodiments, the epitaxial source/drain regions 92 may exert stress on the second nanostructures 54A, 54B, and 54C thereby improving performance. As illustrated in FIG. 12C, the epitaxial source/drain regions 92 are formed in the first recesses 86 such that each dummy gate 76 is disposed between respective neighboring pairs of the epitaxial source/drain regions 92. In some embodiments, the first spacers 81 are used to separate the epitaxial source/drain regions 92 from the dummy gates 76 and the inner spacers 90 are used to separate the epitaxial source/drain regions 92 from the first nanostructures 52A, 52B and 52C by an appropriate lateral distance so that the epitaxial source/drain regions 92 do not short out with subsequently formed gates of the resulting nano-FETs.

Each epitaxial source/drain region 92 may comprise a bottom portion of the epitaxial source/drain region 92A and a top portion of the epitaxial source/drain region 92B. The top portion of the epitaxial source/drain region 92B may be disposed over the bottom portion of the epitaxial source/drain region 92A. The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 (and over the first layer 91 if present), in the n-type region 50N. The epitaxial source/drain regions 92 in the n-type region 50N may include any acceptable material appropriate for n-type nano-FETs. For example, if the second nanostructures 54 are silicon, the epitaxial source/drain regions 92 may include materials exerting a tensile strain on the second nanostructures 54A, 54B, and 54C such as silicon, silicon carbide, phosphorous doped silicon carbide, silicon phosphide, or the like. The epitaxial source/drain regions 92 may have surfaces raised from respective upper surfaces of the nanostructures 55 and may have facets.

To form the epitaxial source/drain regions 92 in the n-type region 50N, a first layer is epitaxially grown in the first recesses 86 (and over the first layer 91 if present) in the n-type region 50N using a first process 73 to form the bottom portions of the epitaxial source/drain region 92A. In an embodiment, the first layer that comprises the bottom portions of the epitaxial source/drain region 92A may have a thickness T1 that is up to 10 nm. After the formation of the bottom portions of the epitaxial source/drain regions 92A in the first recesses 86 in the n-type region 50N, impurities (also referred to as dopants) may be implanted into the bottom portions of the epitaxial source/drain regions 92A in the n-type region 50N, in accordance with embodiments. In other embodiments, the bottom portions of the epitaxial source/drain regions 92A may be in-situ doped during growth. The n-type impurities may comprise arsenic (As), phosphorus (P), sulphur (S), antimony (Sb), or the like. In an embodiment, after implanting the impurities into the bottom portions of the epitaxial source/drain regions 92A in the n-type region 50N, the bottom portions of the epitaxial source/drain regions 92A in the n-type region 50N may have a concentration of impurities (also referred to as a dopant concentration) in a range from about 1×10¹⁵ atoms/cm³ to about 2×10²¹ atoms/cm³.

After the formation of the bottom portions of the epitaxial source/drain regions 92A in the first recesses 86 in the n-type region 50N, a second layer is epitaxially grown in the first recesses 86 and over the bottom portions of the epitaxial source/drain regions 92A in the n-type region 50N using a second process 75 to form the respective top portions of the epitaxial source/drain regions 92B. In an embodiment, the second layer that comprises the top portions of the epitaxial source/drain regions 92B may have a thickness T2 that is in a range from 20 nm to 60 nm. After the formation of the top portions of the epitaxial source/drain regions 92B in the first recesses 86 in the n-type region 50N, impurities (also referred to as dopants) may be implanted into the top portions of the epitaxial source/drain regions 92B in the n-type region 50N, in accordance with embodiments. In other embodiments, the top portions of the epitaxial source/drain regions 92B may be in-situ doped during growth. The n-type impurities may comprise arsenic (As), phosphorus (P), sulphur (S), antimony (Sb), or the like. In an embodiment, after implanting the impurities into the top portions of the epitaxial source/drain regions 92B in the n-type region 50N, the top portions of the epitaxial source/drain regions 92B in the n-type region 50N may have a concentration of impurities (also referred to as a dopant concentration) in a range from about 5×10¹⁵ atoms/cm³ to about 1×10²¹ atoms/cm³. In an embodiment, a dopant concentration of the top portions of the epitaxial source/drain regions 92B in the n-type region 50N may be different to a dopant concentration of the bottom portions of the epitaxial source/drain regions 92A in the n-type region 50N.

In an embodiment, the first process 73 and the second process 75 may each be an epitaxial growth or deposition process such as chemical vapor deposition (CVD), atomic layer deposition (ALD), vapor phase epitaxy (VPE), molecular beam epitaxy (MBE), or the like. In an embodiment, tuning of the parameters of the first process 73 may allow for bottom-up growth of the first layer that comprises the bottom portions of the epitaxial source/drain region 92A in the first recesses 86, such that growth of the first layer takes place at bottom portions of the first recesses 86 before other portions of the first recesses 86. In an embodiment, minimal or minor growth of the first layer may grow on the second nanostructures 54B, and 54C. However, this minimal or minor growth may be less than the amount of bottom-up growth in the first recesses 86. For example, in an embodiment, after the first process 73 is performed, top surfaces of the bottom portions of the epitaxial source/drain region 92A may be below or level with top surfaces of the second nanostructures 54A. In other embodiments, the top surfaces of the bottom portions of the epitaxial source/drain region 92A may be below or level with top surfaces of the second nanostructures 54B. Tuning the parameters of the first process 73 may include tuning gas flows and/or chamber temperature during the first process 73. In an embodiment, each of the first process 73 and the second process 75 may be performed at a temperature that is in a range from 500 °C to 850 °C. In an embodiment, each of the first process 73 and the second process 75 may be performed at a pressure that is in a range from 4 torr to 300 torr. In an embodiment, each of the first process 73 and the second process 75 may be performed using pre-cursor gases that may comprise silane (SiH₄), dichlorosilane (SiH₂Cl₂), hydrogen chloride (HCl), germane (GeH₄), phosphine (PH₃), arsine (AsH₃), a combination thereof, or the like.

After or before the formation of the epitaxial source/drain regions 92 in the n-type region 50N, e.g., the NMOS region, the epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 (and over the first layer 91 if present), in the p-type region 50P. The epitaxial source/drain regions 92 in the p-type region 50P may include any acceptable material appropriate for p-type nano-FETs. For example, if the second nanostructures 54 are silicon, the epitaxial source/drain regions 92 may comprise materials exerting a compressive strain on the second nanostructures 54 such as silicon-germanium, boron doped silicon-germanium, germanium, germanium tin, or the like. The epitaxial source/drain regions 92 may also have surfaces raised from respective surfaces of the nanostructures 55 and may have facets.

To form the epitaxial source/drain regions 92 in the p-type region 50P, a third layer is epitaxially grown in the first recesses 86 (and over the first layer 91 if present) in the p-type region 50P using a third process 77 to form the bottom portions of the epitaxial source/drain region 92A. In an embodiment, the third layer of each of the bottom portions of the epitaxial source/drain region 92A may have the thickness T1 that is up to 10 nm. After the formation of the bottom portions of the epitaxial source/drain regions 92A in the first recesses 86 in the p-type region 50P, impurities (also referred to as dopants) may be implanted into the bottom portions of the epitaxial source/drain regions 92A in the p-type region 50P, in accordance with embodiments. In other embodiments, the bottom portions of the epitaxial source/drain regions 92A may be in-situ doped during growth. The p-type impurities may comprise boron (B), or the like. In an embodiment, after implanting the impurities into the bottom portions of the epitaxial source/drain regions 92A in the p-type region 50P, the bottom portions of the epitaxial source/drain regions 92A in the p-type region 50P may have a concentration of impurities (also referred to as a dopant concentration) in a range from about 3×10¹⁵ atoms/cm³ to about 5×10²⁰ atoms/cm³. In an embodiment, the bottom portions of the epitaxial source/drain regions 92A in the p-type region 50P may have a germanium concentration that is up to 0~50 atomic percent.

After the formation of the bottom portions of the epitaxial source/drain regions 92A in the first recesses 86 in the p-type region 50P, a fourth layer is epitaxially grown in the first recesses 86 and over the bottom portions of the epitaxial source/drain regions 92A in the p-type region 50P using a fourth process 79 to form the respective top portions of the epitaxial source/drain regions 92B. In an embodiment, the fourth layer that comprises the top portions of the epitaxial source/drain regions 92B may have the thickness T2 that is in a range from 20 nm to 60 nm. After the formation of the top portions of the epitaxial source/drain regions 92B in the first recesses 86 in the p-type region 50P, impurities (also referred to as dopants) may be implanted into the top portions of the epitaxial source/drain regions 92B in the p-type region 50P, in accordance with embodiments. In other embodiments, the top portions of the epitaxial source/drain regions 92B may be in-situ doped during growth. The p-type impurities may comprise boron (B), or the like. In an embodiment, after implanting the impurities into the top portions of the epitaxial source/drain regions 92B in the p-type region 50P, the top portions of the epitaxial source/drain regions 92B in the p-type region 50P may have a concentration of impurities (also referred to as a dopant concentration) in a range from about 3×10¹⁸ atoms/cm³ to about 1×10²¹ atoms/cm³. In an embodiment, a dopant concentration of the top portions of the epitaxial source/drain regions 92B in the p-type region 50P may be different to a dopant concentration of the bottom portions of the epitaxial source/drain regions 92A in the p-type region 50P. In an embodiment, the top portions of the epitaxial source/drain regions 92B in the p-type region 50P may have a germanium concentration that is in a range from 40 atomic percent to 60 atomic percent. In an embodiment, a germanium concentration of the top portions of the epitaxial source/drain regions 92B in the p-type region 50P may be different from a germanium concentration of the bottom portions of the epitaxial source/drain regions 92A in the p-type region 50P. In an embodiment, a germanium concentration of the top portions of the epitaxial source/drain regions 92B in the p-type region 50P may be greater than a germanium concentration of the bottom portions of the epitaxial source/drain regions 92A in the p-type region 50P.

In an embodiment, the third process 77 and the fourth process 79 may each be an epitaxial growth or deposition process such as chemical vapor deposition (CVD), atomic layer deposition (ALD), vapor phase epitaxy (VPE), molecular beam epitaxy (MBE), or the like. In an embodiment, tuning of the parameters of the third process 77 may allow for bottom-up growth of the third layer that comprises the bottom portions of the epitaxial source/drain region 92A in the first recesses 86, such that growth of the third layer takes place at bottom portions of the first recesses 86 before other portions of the first recesses 86. In an embodiment, minimal or minor growth of the first layer may grow on the second nanostructures 54B, and 54C. However, this minimal or minor growth may be less than the amount of bottom-up growth in the first recesses 86. For example, in an embodiment, after the third process 77 is performed, top surfaces of the bottom portions of the epitaxial source/drain region 92A may be below or level with top surfaces of the second nanostructures 54A. In other embodiments, the top surfaces of the bottom portions of the epitaxial source/drain region 92A may be below or level with top surfaces of the second nanostructures 54B. Tuning the parameters of the third process 77 may include tuning gas flows and/or chamber temperature during the third process 77. In an embodiment, each of the third process 77 and the fourth process 79 may be performed at a temperature that is in a range from 400 °C to 850 °C. In an embodiment, each of the third process 77 and the fourth process 79 may be performed at a pressure that is in a range from 4 torr to 300 torr. In an embodiment, each of the third process 77 and the fourth process 79 may be performed using pre-cursor gases that may comprise silane (SiH₄), dichlorosilane (SiH₂Cl₂), hydrogen chloride (HCl), germane (GeH₄), borane (BH₃), boron trichloride (BCl₃), Diborane (B₂H₆), a combination thereof, or the like.

As a result of the epitaxy processes (e.g., the first process 73, the second process 75, the third process 77, and the fourth process 79) used to form the epitaxial source/drain regions 92 in the n-type region 50N and the p-type region 50P, upper surfaces of the epitaxial source/drain regions 92 (e.g. the top portions of the epitaxial source/drain regions 92B) have facets which expand laterally outward beyond sidewalls of the nanostructures 55. In some embodiments, these facets cause adjacent epitaxial source/drain regions 92 of a same nano-FET to merge (not shown in the Figures). In other embodiments, adjacent epitaxial source/drain regions 92 remain separated after the epitaxy processes are completed as illustrated by FIG. 12B. In the embodiments illustrated in FIGS. 12B and 12C, the first spacers 81 may be formed to a top surface of the STI regions 68 thereby blocking the epitaxial growth. In some other embodiments, the first spacers 81 may cover portions of the sidewalls of the nanostructures 55 further blocking the epitaxial growth. In some other embodiments, the spacer etch used to form the first spacers 81 may be adjusted to remove the spacer material to allow the epitaxially grown region to extend to the surface of the STI region 68.

FIGS. 12D, 12E, and 12F each illustrate the region 56 of the structure that was shown previously in FIG. 12B. Each of the FIGS. 12D, 12E, and 12F illustrate and describe various features of the epitaxial source/drain regions 92. While presented separately in different figures for purposes of clarity, the features highlighted in each of FIGS. 12D, 12E, and 12F may all be characteristic of the same region 56 shown in FIG. 12B.

FIG. 12D illustrates the region 56 of the structure that was shown previously in FIG. 12B as observed along the <11̅0> crystallographic direction (also referred to subsequently as the specific zone axis). FIG. 12D illustrates that each epitaxial source/drain region 92 comprises a bottom portion of the epitaxial source/drain region 92A and a top portion of the epitaxial source/drain region 92B over the bottom portion of the epitaxial source/drain region 92A. An upper portion 93U of the top portion of the epitaxial source/drain region 92B may have a triangular cross-section with sloping sidewalls that intersect at a topmost point of the top portion of the epitaxial source/drain region 92B. The sloping sidewalls of the upper portion 93U may comprise angled facets that are oriented along the (111) crystallographic plane. A middle portion 93M of the top portion of the epitaxial source/drain region 92B may have sidewalls that comprise facets that are oriented along the (001) crystallographic plane, wherein the upper portion 93U of the top portion of the epitaxial source/drain region 92B is disposed over the middle portion 93M of the top portion of the epitaxial source/drain region 92B, and wherein the upper portion 93U of the top portion of the epitaxial source/drain region 92B and the middle portion 93M of the top portion of the epitaxial source/drain region 92B are disposed over a lower portion 93L of the top portion of the epitaxial source/drain region 92B. The bottom portion of the epitaxial source/drain region 92A may be disposed below the top portion of the epitaxial source/drain region 92B.

FIG. 12E illustrates the region 56 of the structure that was shown previously in FIGS. 12B and 12D as observed along the <11̅0> crystallographic direction (also referred to subsequently as the specific zone axis). FIG. 12D illustrates that each epitaxial source/drain region 92 may have dislocations 95 that are distributed within the epitaxial source/drain region 92, wherein the dislocations 95 are disposed in both the bottom portion of the epitaxial source/drain region 92A and the top portion of the epitaxial source/drain region 92B. The dislocations 95 may comprise edge dislocations and/or screw dislocations. FIG. 12E illustrates that in some embodiments, some dislocations 95 may be disposed close to sidewalls of the epitaxial source/drain region 92. For example, these dislocations 95 may be disposed adjacent to the left sidewalls (as seen in FIG. 12E) of the epitaxial source/drain region 92, and adjacent to the right sidewalls (as seen in FIG. 12E) of the epitaxial source/drain region 92. In an embodiment, some dislocations 95 may originate at the edge regions (e.g., top surfaces, bottom surfaces, and/or surfaces of sidewalls) of the epitaxial source/drain region 92, wherein they may interface with the surrounding material adjacent to the epitaxial source/drain region 92. Other dislocations 95, may be disposed in central regions of the epitaxial source/drain region 92, such as away from both the edge regions and sidewalls of the epitaxial source/drain region 92.

In some embodiments, the slope of the dislocations 95 may be either positive or negative, wherein a dislocation 95 may have a positive slope when the dislocation 95 rises from left to right when observed along the <110> crystallographic direction that is shown in FIGS. 12B, 12D, and 12E, and wherein the dislocation 95 may have a negative slope when the dislocation 95 descends from left to right when observed along the <110> crystallographic direction that is shown in FIGS. 12B, 12D, and 12E. In an embodiment, some of the dislocations 95 may be parallel to each other, wherein these dislocations 95 maintain consistent spacing and orientation throughout their length. Other dislocations 95 may intersect with each other, forming a network of crossing defect lines.

In an embodiment, an angle θ1 between each dislocation 95 (e.g., a dislocation Y and a dislocation Z shown in FIG. 12E) in the epitaxial source/drain region 92 and the horizontal <001> crystallographic direction (represented by a line X-X in FIG. 12E) may be in a range from 30° to 40°. The line X-X may be parallel to a top surface of the substrate 50 (e.g., parallel to the (110) crystallographic plane). In addition, in an embodiment, a number of dislocations 95 in the bottom portion of the epitaxial source/drain region 92A may be smaller than a number of dislocations in the top portion of the epitaxial source/drain region 92B. For example, a ratio of a number of dislocations 95 in the bottom portion of the epitaxial source/drain region 92A to a number of dislocations 95 in the top portion of the epitaxial source/drain region 92B may be in a range from 1:3 to 1:5. In an embodiment, a total number of dislocations 95 in the epitaxial source/drain region 92 may be in a range from 1 dislocation to 999 dislocations.

Advantages can be achieved by forming the fins 66 that protrude from a top surface of the substrate 50, wherein top surfaces of the fins 66 and the substrate 50 are oriented along the (110) crystallographic plane. The first recesses 86 are formed in the nanostructures 55 and the fins 66. In an embodiment, bottom surfaces of the first recesses 86 in the fins 66 may be substantially coplanar with the (110) crystallographic plane of the substrate 50. The bottom portions of the epitaxial source/drain regions 92A are then epitaxially grown in the first recesses 86 using the first process 73 or the third process 77, and the top portions of the epitaxial source/drain regions 92B are then formed over respective bottom portions of the epitaxial source/drain regions 92A using the second process 75 or the fourth process 79, wherein a doping concentration and/or germanium concentration of the top portions of the epitaxial source/drain regions 92B is different from a doping concentration and/or germanium concentration of the respective bottom portions of the epitaxial source/drain regions 92A. After the formation of the epitaxial source/drain regions 92, an angle between each dislocation 95 in each epitaxial source/drain regions 92 and the horizontal <001> crystallographic direction may be in a range from 30° to 40°, wherein the dislocation 95 in the epitaxial source/drain region 92 is observed along the <110> crystallographic direction (also referred to subsequently as the specific zone axis). In addition, a ratio of a number of dislocations 95 in each bottom portion of the epitaxial source/drain region 92A to a number of dislocations 95 in a respective top portion of the epitaxial source/drain region 92B may be in a range from 1:3 to 1:5. Further, a total number of dislocations 95 in each epitaxial source/drain region 92 may be equal to or smaller than 999 dislocations.

These advantages include the forming of the epitaxial source/drain regions 92 in the first recesses 86 in the fins 66, wherein the bottom surfaces of the first recesses 86 in the fins 66 may be substantially coplanar with the (110) crystallographic plane of the substrate 50 allowing for improved control of dislocation patterns in the epitaxial source/drain regions 92. For example, an angle between each dislocation 95 in each epitaxial source/drain regions 92 and the horizontal <001> direction may be controlled to be in a range from 30° to 40°. This improved control of dislocation patterns may lead to an improved strain distribution in the channel regions 60 of the nanostructures 55. As a result, carrier mobility may be increased, and device performance is therefore enhanced. In addition, the tuning of the parameters of the first process 73 or the third process 77, and the second process 75 or the fourth process 79 that are used to form the epitaxial source/drain regions 92 in the first recesses 86 in the nanostructures 55 and the fins 66, wherein the bottom surfaces of the first recesses 86 in the fins 66 may be substantially coplanar with the (110) crystallographic plane of the substrate 50, allows for a tuning of a ratio between a number of dislocations 95 in each bottom portion of the epitaxial source/drain region 92A to a number of dislocations 95 in a respective top portion of the epitaxial source/drain region 92B to be in a range from 1:3 to 1:5. In addition, a total number of dislocations 95 in each epitaxial source/drain region 92 may be controlled to be equal to or smaller than 999 dislocations. This allows for carrier scattering in the epitaxial source/drain region 92 to be controlled and even reduced, which directly improves electron mobility and overall current flow. As a result, device performance and reliability is improved.

FIG. 12F illustrates the region 56 of the structure that was shown previously in FIGS. 12B, 12D, and 12E as observed along the <110> crystallographic direction (also referred to subsequently as the specific zone axis). FIG. 12F illustrates that in an embodiment, each dislocation 95 (e.g., the dislocation Y) in the epitaxial source/drain region 92 may have a length L1 that is equal to or smaller than 30 nm. For example, the length L1 may be in a range that is from 1 nm to 30 nm. In an embodiment, each dislocation 95 (e.g., the dislocation Y) in the epitaxial source/drain region 92 may have a width W1 that is in a range from 0.01 to 0.1 nm, wherein the width W1 is a lateral extent of the region within the crystal lattice of the epitaxial source/drain region 92 where atomic positions deviate significantly from their ideal locations due to the presence of the dislocation 95. In an embodiment, the top portion of the epitaxial source/drain region 92B may have facets which expand laterally outward beyond sidewalls of the nanostructures 55 and sidewalls of the bottom portion of the epitaxial source/drain region 92A. In an embodiment, the top portion of the epitaxial source/drain region 92B may have a width W2 that is in a range from 10 nm to 50 nm, and the bottom portion of the epitaxial source/drain region 92A may have a width W3, wherein the width W2 is greater than the width W3.

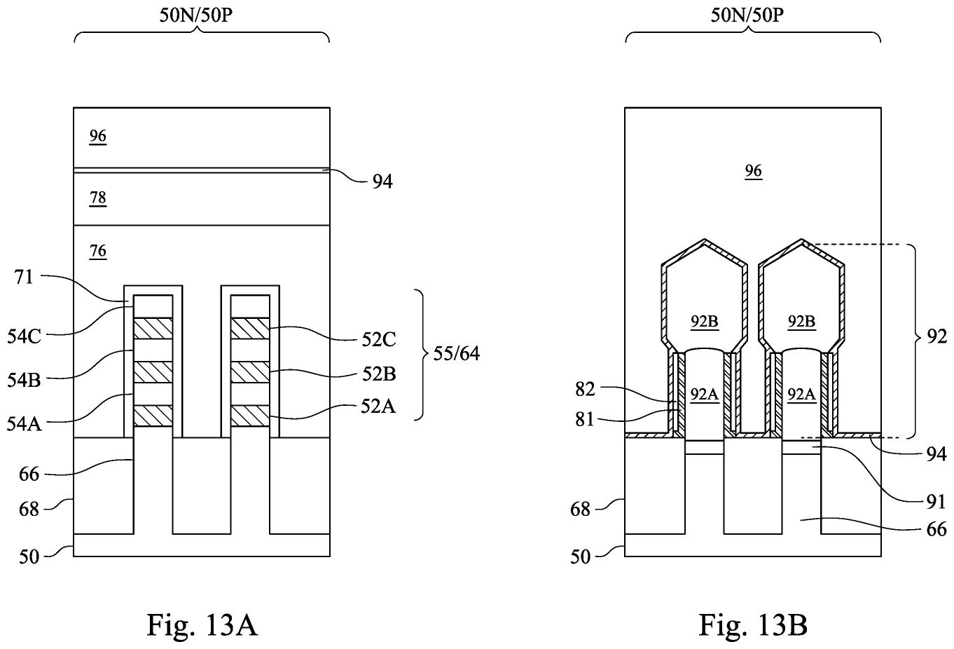

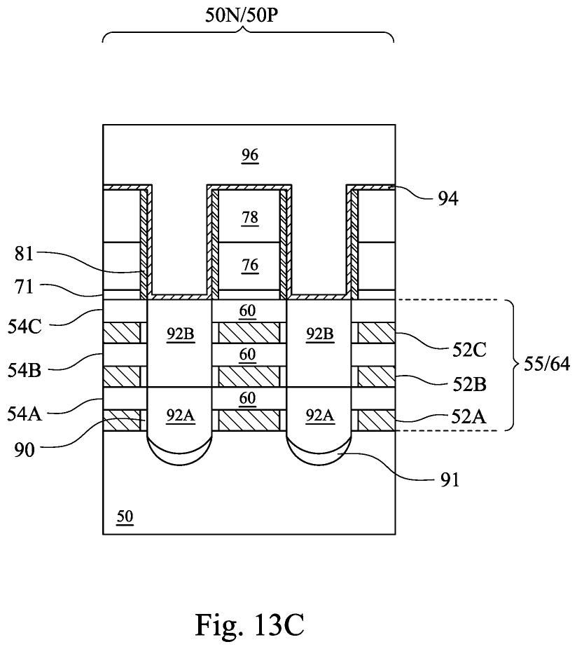

In FIGS. 13A through 13C, a first interlayer dielectric (ILD) 96 is deposited over the structure illustrated in FIGS. 12A through 12C. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the first spacers 81. The CESL 94 may comprise a dielectric material, such as, silicon nitride, silicon oxide, silicon oxynitride, or the like, having a different etch rate than the material of the overlying first ILD 96.

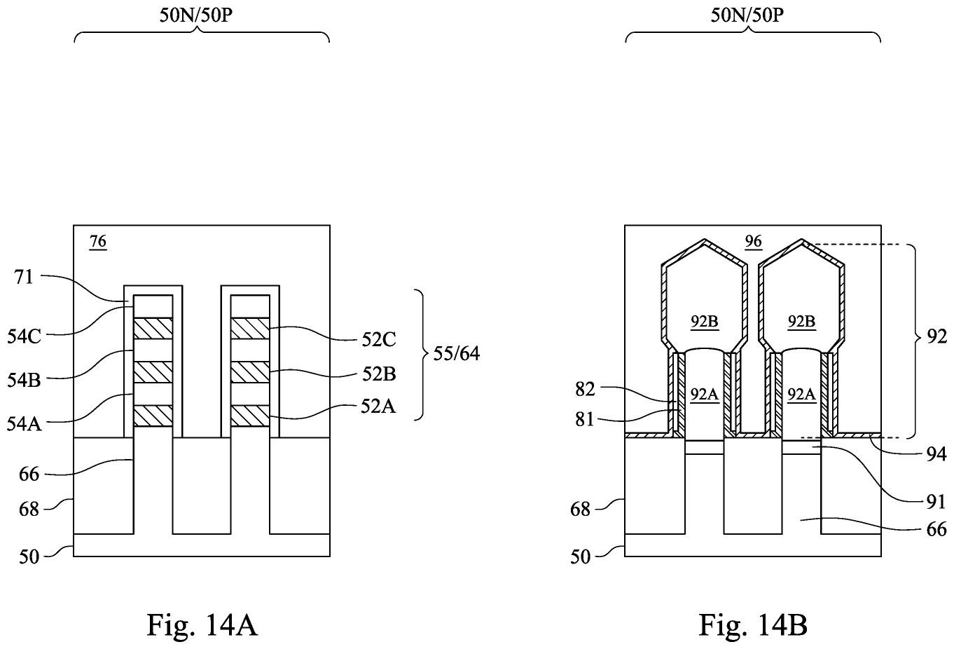

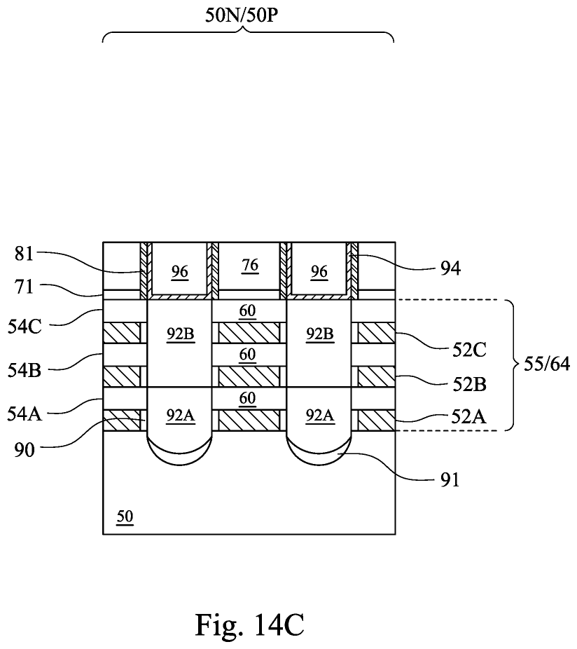

In FIGS. 14A through 14C, a planarization process, such as a CMP, may be performed to level the top surface of the first ILD 96 with the top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, and the first ILD 96 are level. Accordingly, the top surfaces of the dummy gates 76 are exposed through the first ILD 96. In some embodiments, the masks 78 may remain, in which case the planarization process levels the top surface of the first ILD 96 with top surface of the masks 78, and the first spacers 81.

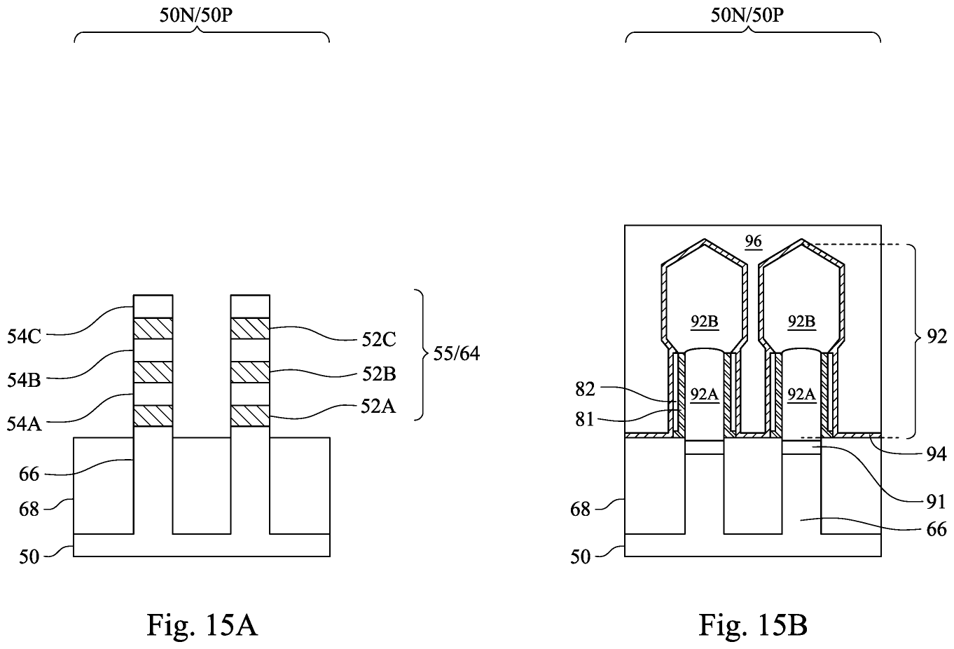

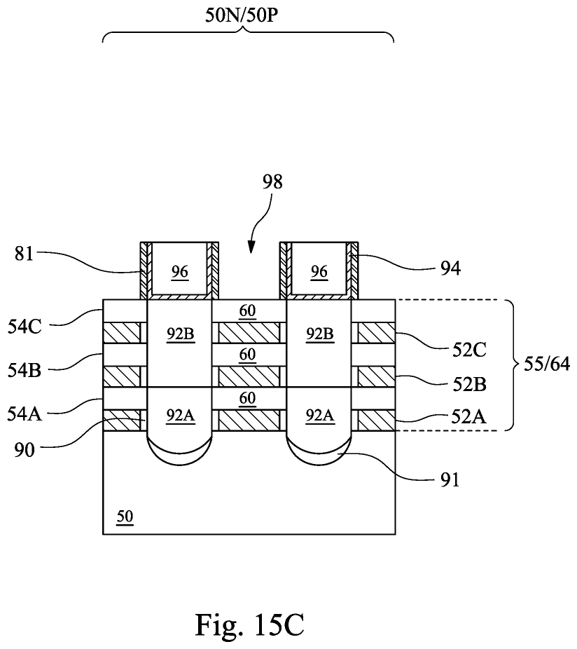

In FIGS. 15A through 15C, the dummy gates 76, and the masks 78 if present, are removed in an etching step(s), so that recesses 98 are formed. Portions of the dummy gate dielectrics 71 in the recesses 98 may also be removed. In some embodiments, only the dummy gates 76 are removed and the dummy gate dielectrics 71 remain and are exposed by the recesses 98. In some embodiments, the dummy gate dielectrics 71 are removed from recesses 98 in a first region of a die (e.g., a core logic region) and remains in recesses 98 in a second region of the die (e.g., an input/output region). In some embodiments, the dummy gates 76 are removed by an anisotropic dry etch process. For example, the etching process may include a dry etch process using reaction gas(es) that selectively etch the dummy gates 76 without etching the first ILD 96 and the first spacers 81. Each recess 98 exposes and/or overlies the multi-layer stacks 64. Portions of the multi-layer stacks 64 are disposed between neighboring pairs of the epitaxial source/drain regions 92. During the removal, the dummy gate dielectrics 71 may be used as an etch stop layer when the dummy gates 76 are etched. The dummy gate dielectrics 71 may then be optionally removed after the removal of the dummy gates 76.

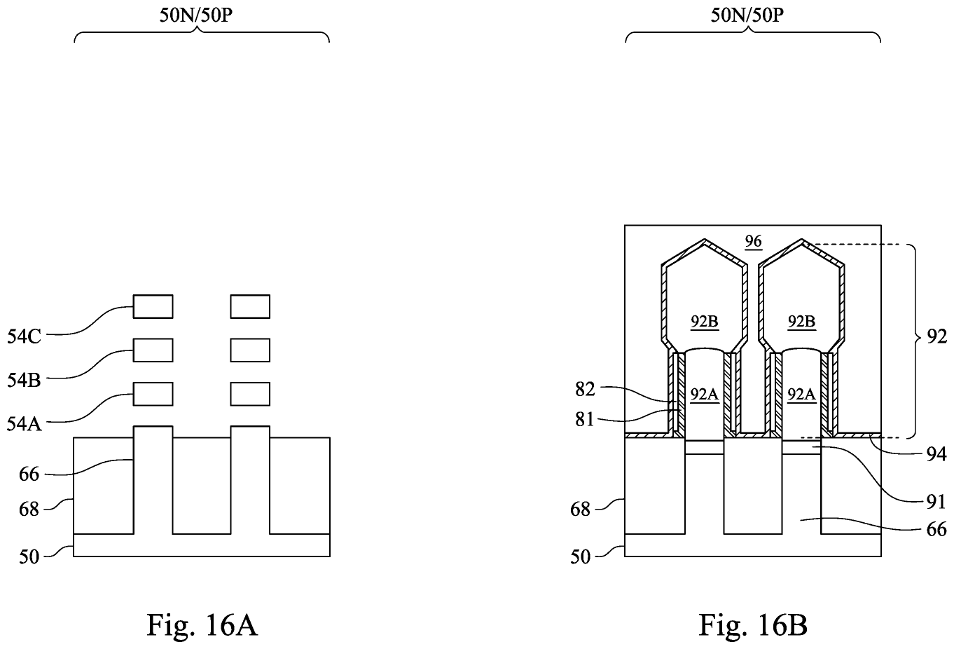

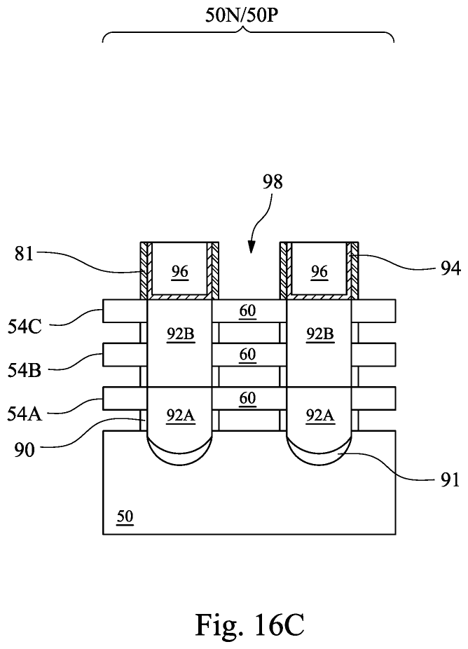

In FIGS. 16A through 16C, the first nanostructures 52A, 52B and 52C are removed from the regions 50N and the region 50P. The first nanostructures 52A, 52B and 52C may be removed by isotropic etching processes such as wet etching, dry etching, or the like. The etchants used to remove the first nanostructures 52A, 52B and 52C may be selective to the materials of the second nanostructures 54A, 54B and 54C. The second nanostructures 54A, 54B and 54C may also be subsequently referred to as channel layers 54A, 54B and 54C, respectively. The second nanostructures 54A, 54B, and 54C between adjacent epitaxial source/drain regions 92 may additionally be referred to as the channel regions 60. In an embodiment in which first nanostructures 52A, 52B and 52C comprise the first semiconductor material (e.g., SiGe, or the like) and the second nanostructures 54A, 54B and 54C comprise the second semiconductor material (e.g., Si, SiC, or the like), a fluorine-based etchant, such as hydrogen fluoride (HF) or the like may be used remove layers of the multi-layer stack 64 in the regions 50N and region 50P.

In FIGS. 17A through 17C, gate dielectric layers 120 and gate electrodes 102 are formed for replacement gates. The gate dielectric layers 120 are deposited conformally in the recesses 98. The gate dielectric layers 120 may be formed on top surfaces, sidewalls, and bottom surfaces of the second nanostructures 54A, 54B and 54C. The gate dielectric layers 120 may also be deposited on top surfaces of the first ILD 96, the CESL 94, the first spacers 81, and the STI regions 68 and on sidewalls of the first spacers 81 and the inner spacers 90.

In accordance with some embodiments, the gate dielectric layers 120 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 120 include a high-k dielectric material, and in these embodiments, the gate dielectric layers 120 may have a k-value greater than about 7.0, and may include a metal oxide or a silicate of hafnium, aluminum, zirconium, lanthanum, manganese, barium, titanium, lead, and combinations thereof. The structure of the gate dielectric layers 120 may be the same or different in the n-type region 50N and the p-type region 50P. The formation methods of the gate dielectric layers 120 may include molecular-beam Deposition (MBD), ALD, PECVD, and the like.

The gate electrodes 102 are deposited over the gate dielectric layers 120, respectively, and fill the remaining portions of the recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 17A through 17C, the gate electrodes 102 may comprise any number of liner layers, any number of work function tuning layers, and a fill material. Any combination of the layers which make up the gate electrodes 102 may be deposited between adjacent ones of the second nanostructures 54.

The formation of the gate dielectric layers 120 in the n-type region 50N and the p-type region 50P may occur simultaneously such that the gate dielectric layers 120 in each region are formed from the same materials, and the formation of the gate electrodes 102 may occur simultaneously such that the gate electrodes 102 in each region are formed from the same materials. In some embodiments, the gate dielectric layers 120 in each region may be formed by distinct processes, such that the gate dielectric layers 120 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the recesses 98, a planarization process, such as a CMP, may be performed to remove the excess portions of the gate dielectric layers 120 and the material of the gate electrodes 102, which excess portions are over the top surface of the first ILD 96. The remaining portions of material of the gate electrodes 102 and the gate dielectric layers 120 thus form replacement gate structures of the resulting nano-FETs. The gate electrodes 102 and the gate dielectric layers 120 may be collectively referred to as “gate structures.” The gate electrodes 102 and the gate dielectric layers 120 may also be collectively referred to as “gate stacks.

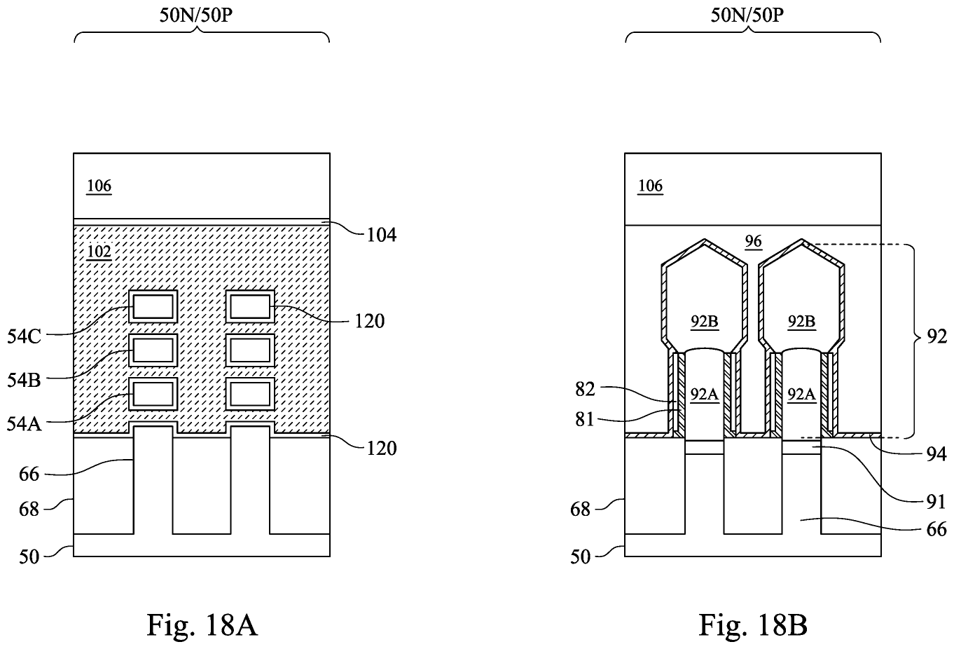

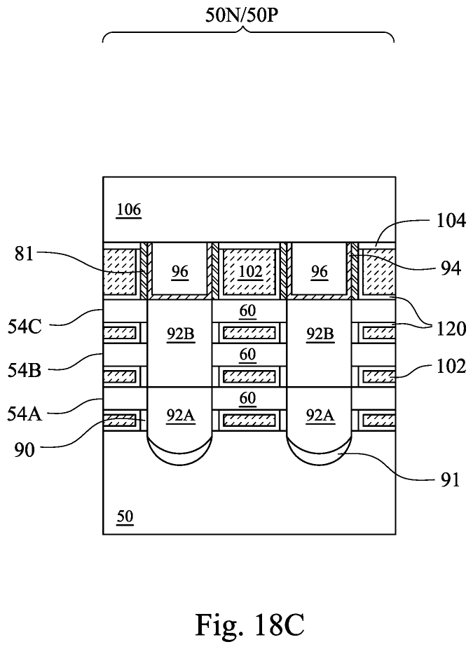

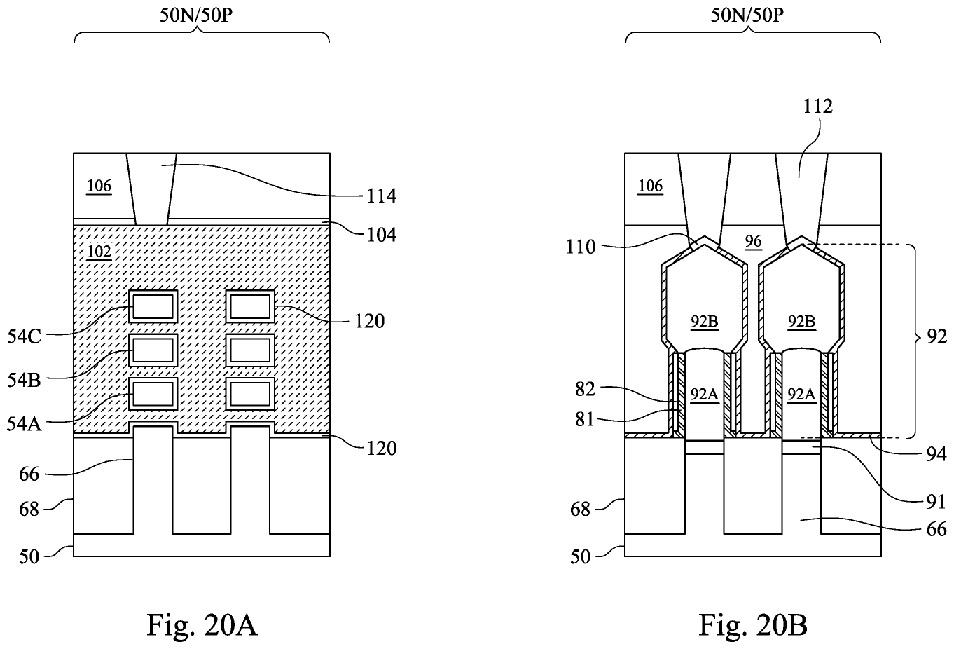

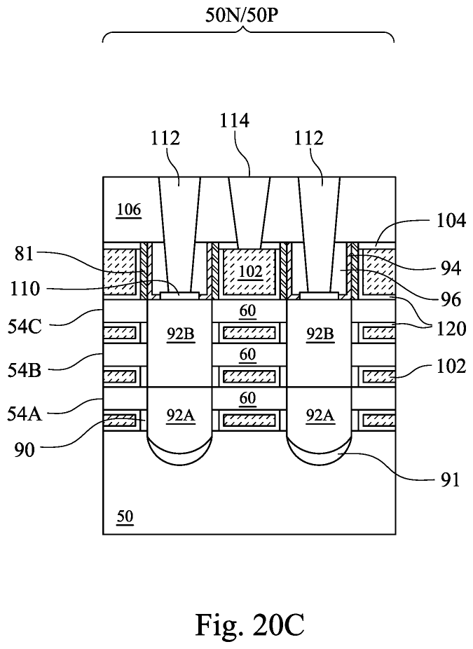

In FIGS. 18A through 18C, the gate structures (including the gate dielectric layers 120 and the corresponding overlying gate electrodes 102) are recessed, so that recess are formed directly over the gate structures and between opposing portions of the first spacers 81. Gate masks 104 comprising one or more layers of dielectric material, such as silicon nitride, silicon oxynitride, or the like, are filled in the recesses, followed by a planarization process to remove excess portions of the dielectric material extending over the first ILD 96. Subsequently formed gate contacts (such as the gate contacts 114, discussed below with respect to FIGS. 20A through 20C) penetrate through the gate masks 104 to contact the top surfaces of the recessed gate electrodes 102.

As further illustrated by FIGS. 18A through 18C, a second ILD 106 is deposited over the first ILD 96 and over the gate masks 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

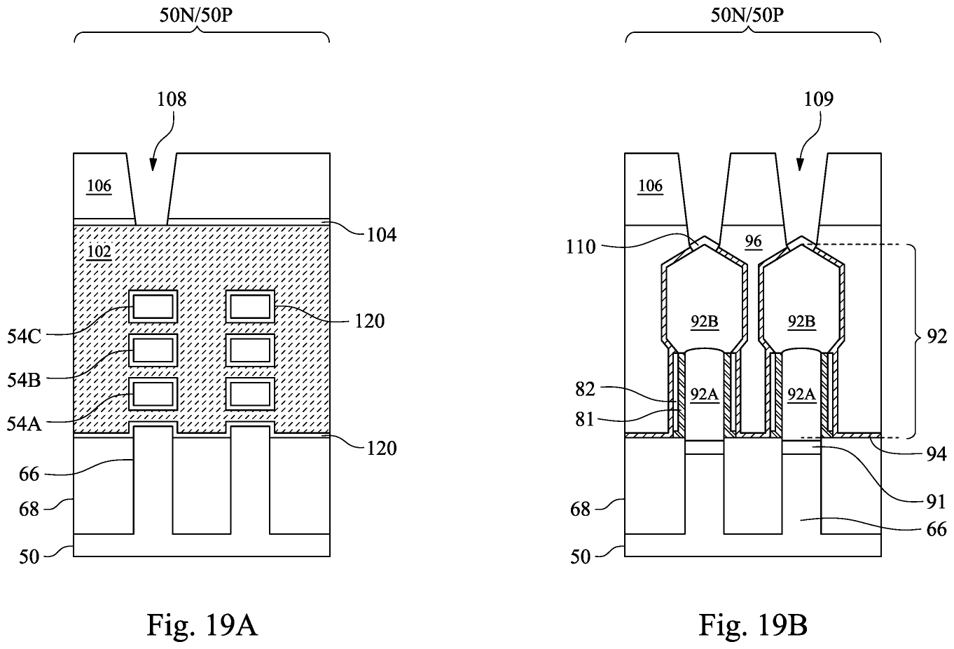

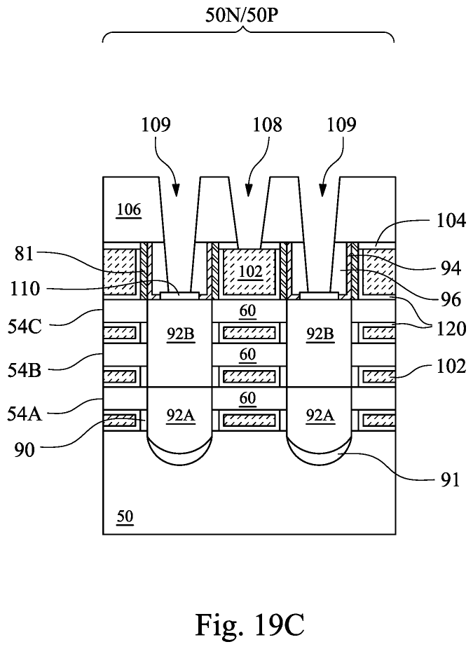

In FIGS. 19A through 19C, openings 108 for gate contacts 114 (shown subsequently in FIGS. 20A through 20C) are formed through the second ILD 106 and the gate mask 104, and openings 109 for source/drain contacts 112 (shown subsequently in FIG. 20B) are formed through the second ILD 106 and the first ILD 96. The openings 108 and 109 may be formed using acceptable photolithography and etching techniques. The openings 108 may expose surfaces of the gate structures and the openings 109 may expose surfaces of the epitaxial source/drain regions 92. Silicide regions 110 are formed over the epitaxial source/drain regions 92 by first depositing a metal (not separately illustrated) capable of reacting with the semiconductor materials of the underlying epitaxial source/drain regions 92 (e.g. silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, and then performing a thermal anneal process to form the silicide regions 110. The un-reacted portions of the deposited metal are then removed, e.g., by an etching process. The Silicide regions 110 may have a higher conductivity than the epitaxial source/drain regions 92. The silicide regions 110 form a low-resistance interface between the epitaxial source/drain regions 92 and subsequently formed source/drain contacts 112 (shown in FIG. 20B), As a result, contact resistance between the source/drain contacts 112 and the epitaxial source/drain regions 92 can be reduced.

In FIGS. 20A through 20C, a liner, such as a diffusion barrier layer, an adhesion layer, or the like, and a conductive material are formed in the openings 108 and 109. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106. The remaining liner and conductive material form gate contacts 114 in the openings 108, and form source/drain contacts 112 in the openings 109. The gate contacts 114 are physically and electrically coupled to the gate electrodes 102, and the source/drain contacts 112 are physically and electrically coupled to the epitaxial source/drain regions 92.

The embodiments of the present disclosure have some advantageous features. The embodiments include forming semiconductor nanostructures over a semiconductor fin and a semiconductor substrate. The semiconductor fin may be formed to protrude from the semiconductor substrate, wherein top surfaces of the semiconductor fin and the semiconductor substrate are oriented along the (110) crystallographic plane. A recess is formed in the semiconductor nanostructures and the semiconductor fin. In an embodiment, bottom surfaces of the recess in the semiconductor fin may be substantially coplanar with the (110) crystallographic plane of the semiconductor substrate. For example, bottom surfaces of the recess in the semiconductor fin may be oriented along the (110) crystallographic plane, which may influence the properties of a source/drain region that is subsequently formed in the recess. The source/drain region is then formed in the recess. For example, the source/drain region may be formed by performing a first process to epitaxially grow a first portion of the source/drain region in the recess, and subsequently performing a second process to epitaxially grow a second portion of the source/drain region over the first portion of the source/drain region. After the formation of the source/drain region, an angle between each dislocation in the source/drain region and the horizontal <001> direction may be in a range from 30° to 40°, wherein the dislocation in the source/drain region is observed along the <110> crystallographic direction (also referred to subsequently as the specific zone axis). In addition a number of dislocations in the first portion of the source/drain region is smaller than a number of dislocations in the second portion of the source/drain region. Further, when observed along the <110> crystallographic direction, the second portion of the source/drain region may comprise a top portion having a triangular cross-section with sloping sidewalls that intersect at a topmost point of the top portion of the second portion of the source/drain region. The sloping sidewalls may comprise angled facets that are oriented along the (111) crystallographic plane. A bottom portion of the second portion of the source/drain region may be disposed below the top portion of the second portion of the source/drain region. The advantages of the embodiments disclosed herein may include the forming of the source/drain region in the recess in the semiconductor nanostructures and the semiconductor fin using the first process and the second process, wherein the bottom surfaces of the recess in the semiconductor fin may be substantially coplanar with the (110) crystallographic plane of the semiconductor substrate allowing for improved control of dislocation patterns in the source/drain region (e.g., an angle between each dislocation in the source/drain region and the horizontal <001> direction may be in a range from 30° to 40°), and improved strain distribution in channel regions of the semiconductor nanostructures. This results in an increase in carrier mobility, and hence device performance is enhanced. In addition, the use of the first process and the second process to form the source/drain region in the recess in the semiconductor nanostructures and the semiconductor fin, wherein the bottom surfaces of the recess in the semiconductor fin may be substantially coplanar with the (110) crystallographic plane of the semiconductor substrate, allows for the source/drain region to be formed with a smaller number of dislocations in the source/drain region. This may lead to reduced carrier scattering, which directly improves electron mobility and overall current flow. As a result, device performance and reliability is improved.

In accordance with an embodiment, a method includes depositing a multi-layer stack on a semiconductor substrate, the multi-layer stack including a plurality of sacrificial layers that alternate with a plurality of channel layers, where a top surface of the semiconductor substrate is parallel to the (110) crystallographic plane; etching the multi-layer stack and the semiconductor substrate to form a fin; forming a dummy gate on a top surface and sidewalls of the fin; forming a first spacer on a sidewall of the dummy gate; forming a first recess in the fin adjacent the dummy gate, where a bottom surface of the first recess in the fin is coplanar with the (110) crystallographic plane; and forming an epitaxial source/drain region in the first recess, where the epitaxial source/drain region includes a bottom portion of the epitaxial source/drain region; and a top portion of the epitaxial source/drain region over the bottom portion of the epitaxial source/drain region, where when observed along the <110> crystallographic direction, a number of dislocations in the top portion of the epitaxial source/drain region is greater than a number of dislocations in the bottom portion of the epitaxial source/drain region. In an embodiment, forming the epitaxial source/drain region in the first recess includes performing a first epitaxial growth process to form the bottom portion of the epitaxial source/drain region; and performing a second epitaxial growth process to form the top portion of the epitaxial source/drain region over the bottom portion of the epitaxial source/drain region, where a thickness of the bottom portion of the epitaxial source/drain region is smaller than a thickness of the top portion of the epitaxial source/drain region. In an embodiment, a dopant concentration of the top portion of the epitaxial source/drain region is different to a dopant concentration of the bottom portion of the epitaxial source/drain region. In an embodiment, when observed along the <11̅0> crystallographic direction, an upper portion of the top portion of the epitaxial source/drain region has a triangular cross-section having sloping sidewalls that intersect at a topmost point of the top portion of the epitaxial source/drain region, and where the sloping sidewalls of the upper portion include angled facets that are oriented along the (111) crystallographic plane. In an embodiment, a ratio of the number of dislocations in the bottom portion of the epitaxial source/drain region to the number of dislocations in the top portion of the epitaxial source/drain region is in a range from 1:3 to 1:5. In an embodiment, when observed along the <11̅0> crystallographic direction, a total number of dislocations in the epitaxial source/drain region is in a range from 1 dislocation to 999 dislocations. In an embodiment, when observed along the <11̅0> crystallographic direction, an angle between each dislocation in the epitaxial source/drain region and the <001> crystallographic direction is in a range from 30° to 40°.

In accordance with an embodiment, a method includes depositing a first sacrificial layer and a first channel layer sequentially over a semiconductor substrate, where a top surface of the semiconductor substrate is parallel to the (110) crystallographic plane; patterning the first sacrificial layer, the first channel layer, and the semiconductor substrate to form a fin structure that protrudes from the semiconductor substrate; forming a dummy gate on a top surface and sidewalls of the fin structure; forming a first recess in the fin structure adjacent the dummy gate, where a bottom surface of the first recess in the fin structure is coplanar with the (110) crystallographic plane, where the bottom surface of the first recess is disposed below a bottom surface of the first sacrificial layer; and forming an epitaxial source/drain region in the first recess, where forming the epitaxial source/drain region includes performing a first epitaxial growth process to form a bottom portion of the epitaxial source/drain region; and performing a second epitaxial growth process to form a top portion of the epitaxial source/drain region over the bottom portion of the epitaxial source/drain region, where when observed along the <11̅0> crystallographic direction, an angle between each dislocation in the epitaxial source/drain region and the <001> crystallographic direction is in a range from 30° to 40°. In an embodiment, when observed along the <11̅0> crystallographic direction, each dislocation in the epitaxial source/drain region has a length that is 30 nm or less. In an embodiment, a dopant concentration of the top portion of the epitaxial source/drain region is different to a dopant concentration of the bottom portion of the epitaxial source/drain region. In an embodiment, a germanium concentration of the top portion of the epitaxial source/drain region is greater than a germanium concentration of the bottom portion of the epitaxial source/drain region. In an embodiment, when observed along the <11̅0> crystallographic direction, a number of dislocations in the top portion of the epitaxial source/drain region is greater than a number of dislocations in the bottom portion of the epitaxial source/drain region. In an embodiment, a ratio of the number of dislocations in the bottom portion of the epitaxial source/drain region to the number of dislocations in the top portion of the epitaxial source/drain region is in a range from 1:3 to 1:5. In an embodiment, a thickness of the bottom portion of the epitaxial source/drain region is up to 10 nm, and a thickness of the top portion of the epitaxial source/drain region is in a range from 20 nm to 60 nm.

In accordance with an embodiment, a semiconductor device includes a first channel layer over a semiconductor substrate; a second channel layer over the first channel layer; a gate structure wrapping around the first channel layer and the second channel layer; a first epitaxial source/drain region and a second epitaxial source/drain region at opposing sides of the gate structure, the first channel layer, and the second channel layer, where the first epitaxial source/drain region includes a bottom portion of the first epitaxial source/drain region; and a top portion of the first epitaxial source/drain region over the bottom portion of the first epitaxial source/drain region, where when observed along the <11̅0> crystallographic direction, an angle between each dislocation in the first epitaxial source/drain region and the <001> crystallographic direction is in a range from 30° to 40°. In an embodiment, when observed along the <11̅0> crystallographic direction, a number of dislocations in the top portion of the first epitaxial source/drain region is greater than a number of dislocations in the bottom portion of the first epitaxial source/drain region. In an embodiment, a ratio of the number of dislocations in the bottom portion of the first epitaxial source/drain region to the number of dislocations in the top portion of the first epitaxial source/drain region is in a range from 1:3 to 1:5. In an embodiment, when observed along the <11̅0> crystallographic direction, an upper portion of the top portion of the first epitaxial source/drain region has a triangular cross-section having sloping sidewalls that intersect at a topmost point of the top portion of the first epitaxial source/drain region, and where the sloping sidewalls of the upper portion include angled facets that are oriented along the (111) crystallographic plane. In an embodiment, when observed along the <11̅0> crystallographic direction, each dislocation in the first epitaxial source/drain region has a length that is 30 nm or less. In an embodiment, a dopant concentration of the top portion of the first epitaxial source/drain region is different to a dopant concentration of the bottom portion of the first epitaxial source/drain region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first channel layer disposed between a first epitaxial source/drain region and a second epitaxial source/drain region, the first channel layer being disposed over a semiconductor substrate, wherein top surfaces of the semiconductor substrate are oriented along the (110) crystallographic plane;
a gate structure wrapping around the first channel layer and disposed between the first epitaxial source/drain region and the second epitaxial source/drain region, wherein the first epitaxial source/drain region comprises:
a bottom portion of the first epitaxial source/drain region; and
a top portion of the first epitaxial source/drain region over the bottom portion of the first epitaxial source/drain region, wherein when observed along the <11̅0> crystallographic direction, a number of dislocations in the top portion of the first epitaxial source/drain region is greater than a number of dislocations in the bottom portion of the first epitaxial source/drain region.

2. The semiconductor device of claim 1, wherein a ratio of the number of dislocations in the bottom portion of the first epitaxial source/drain region to the number of dislocations in the top portion of the first epitaxial source/drain region is in a range from 1:3 to 1:5.

3. The semiconductor device of claim 1, wherein when observed along the <110> crystallographic direction, an angle between each dislocation in the first epitaxial source/drain region and the <001> crystallographic direction is in a range from 30° to 40°.

4. The semiconductor device of claim 1, wherein when observed along the <11̅0> crystallographic direction, each dislocation in the first epitaxial source/drain region has a length that is 30 nm or less.

5. The semiconductor device of claim 1, wherein a dopant concentration of the top portion of the first epitaxial source/drain region is different to a dopant concentration of the bottom portion of the first epitaxial source/drain region.

6. The semiconductor device of claim 1, wherein a germanium concentration of the top portion of the first epitaxial source/drain region is different to a germanium concentration of the bottom portion of the first epitaxial source/drain region.

7. The semiconductor device of claim 1, wherein the top portion of the first epitaxial source/drain region has a thickness that is in a range from 20 nm to 60 nm.

8. A semiconductor device comprising:
a channel region over a fin and extending between a first epitaxial source/drain region and a second epitaxial source/drain region;
a gate structure over the fin and wrapping around the channel region, wherein the first epitaxial source/drain region comprises:
a bottom portion of the first epitaxial source/drain region; and
a top portion of the first epitaxial source/drain region over the bottom portion of the first epitaxial source/drain region, wherein a dopant concentration of the top portion of the first epitaxial source/drain region is different to a dopant concentration of the bottom portion of the first epitaxial source/drain region, and wherein a germanium concentration of the top portion of the first epitaxial source/drain region is different to a germanium concentration of the bottom portion of the first epitaxial source/drain region.

9. The semiconductor device of claim 8, wherein the top portion of the first epitaxial source/drain region has a thickness that is in a range from 20 nm to 60 nm.

10. The semiconductor device of claim 8, wherein when observed along the <110> crystallographic direction, each dislocation in the first epitaxial source/drain region has a length that is 30 nm or less.

11. The semiconductor device of claim 8, wherein a ratio of a number of dislocations in the bottom portion of the first epitaxial source/drain region to a number of dislocations in the top portion of the first epitaxial source/drain region is in a range from 1:3 to 1:5.

12. The semiconductor device of claim 8, wherein when observed along the <11̅0> crystallographic direction, an angle between each dislocation in the first epitaxial source/drain region and the <001> crystallographic direction is in a range from 30° to 40°.

13. The semiconductor device of claim 8, wherein when observed along the <11̅0> crystallographic direction, a number of dislocations in the top portion of the first epitaxial source/drain region is greater than a number of dislocations in the bottom portion of the first epitaxial source/drain region.

14. A method comprising:
forming a fin on a semiconductor substrate, the fin comprising a plurality of sacrificial layers that alternate with a plurality of channel layers, wherein a top surface of the semiconductor substrate is parallel to the (110) crystallographic plane;
forming a dummy gate on a top surface and sidewalls of the fin;
etching the fin to form a first recess adjacent the dummy gate, wherein a bottom surface of the first recess in the fin is coplanar with the (110) crystallographic plane; and
forming an epitaxial source/drain region in the first recess, wherein the epitaxial source/drain region comprises:
a bottom portion of the epitaxial source/drain region; and
a top portion of the epitaxial source/drain region over the bottom portion of the epitaxial source/drain region, wherein a dopant concentration of the top portion of the epitaxial source/drain region is different to a dopant concentration of the bottom portion of the epitaxial source/drain region.

15. The method of claim 14, wherein when observed along the <11̅0> crystallographic direction, an angle between each dislocation in the epitaxial source/drain region and the <001> crystallographic direction is in a range from 30° to 40°.

16. The method of claim 15, wherein when observed along the <11̅0> crystallographic direction, a number of dislocations in the top portion of the epitaxial source/drain region is greater than a number of dislocations in the bottom portion of the epitaxial source/drain region.

17. The method of claim 16, wherein a ratio of the number of dislocations in the bottom portion of the epitaxial source/drain region to the number of dislocations in the top portion of the epitaxial source/drain region is in a range from 1:3 to 1:5.

18. The method of claim 14, wherein when observed along the <11̅0> crystallographic direction, each dislocation in the epitaxial source/drain region has a length that is 30 nm or less.

19. The method of claim 14, wherein a germanium concentration of the top portion of the epitaxial source/drain region is different to a germanium concentration of the bottom portion of the epitaxial source/drain region.

20. The method of claim 14, wherein when observed along the <11̅0> crystallographic direction, a total number of dislocations in the epitaxial source/drain region is in a range from 1 dislocation to 999 dislocations.
